(19) United States
(12) Patent Application Publication
(10) Pub. No.: US 2026/0033008 A1
(43) Pub. Date: Jan. 29, 2026

(54) TAP CELLS WITHOUT GATE AND METHODS OF FABRICATION THEREOF

(71) Applicant: TAIWAN SEMICONDUCTOR MANUFACTURING COMPANY, LTD., Hsinchu (TW)

(72) Inventors: Sung-Hsin YANG, Tainan (TW); Chen-Chieh CHIANG, Kaohsiung (TW); Jia-Ren CHEN, Tainan (TW); Zhong-Yi CHEN, Tainan (TW); Chih-Hsin KO, Kaohsiung (TW)

(21) Appl. No.: 18/964,140

(22) Filed: Nov. 29, 2024

Related U.S. Application Data
(60) Provisional application No. 63/675,310, filed on Jul. 25, 2024.

(51) Int. Cl. H10D 89/10; H10D 30/01; H10D 30/62; H10D 62/13; H10D 84/01; H10D 84/83

(52) U.S. Cl. CPC H10D 89/10; H10D 30/024; H10D 30/6219; H10D 62/151; H10D 84/0128; H10D 84/013; H10D 84/0158; H10D 84/834

(57) ABSTRACT

Embodiments of the present disclosure provide a semiconductor device including pick-up components, such as TAP cells, without gate structures and methods for forming the semiconductor devices.

### CROSS-REFERENCE TO RELATED APPLICATIONS

This application claims priority to the U.S. Provisional Patent Application Ser. No. 63/675,310 filed Jul. 25, 2024, which is incorporated by reference in its entirety.

### BACKGROUND

As integrated circuits become smaller in physical size, and the quantity of transistors included in the device increases, smaller line widths are used in the integrated circuits, and the transistors therein are located closer together. Latch-up is a type of short circuit that sometimes occurs in integrated circuits. To prevent latch-up, some integrated circuits include tap cells. Since the tap cells need to be placed with appropriate distances from each other, the integrated circuit may include many tap cells which result in increasing the overall size of the integrated circuit.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of a layout design including a tap cell according to embodiments of the present disclosure.

FIG. 2A is a diagram of an integrated circuit layout including tap cells according to embodiments of the present disclosure.

FIG. 2B is a partial enlarged view of the integrated circuit layout of FIG. 2A.

FIGS. 2C-2D are cross sectional vies of the integrated circuit layout of FIG. 2A.

FIG. 3A is a diagram of an integrated circuit layout including tap cells according to embodiments of the present disclosure.

FIG. 3B is a partial enlarged view of the integrated circuit layout of FIG. 3A.

FIGS. 3C-3D are cross sectional vies of the integrated circuit layout of FIG. 3A.

FIGS. 4A-4B, 5A-5B, 6A-6B, 7A-7B, 8A-8B, 9A-9B, 10A-10B, 11A-11B, 12, 13, 14A, 14B, 14C, and 14D schematically demonstrate various stages of forming an integrated circuit including tap cells according to the present disclosure.

FIGS. 15A-15B schematically illustrate schematically illustrate an integrated circuit structure according to embodiments of the present disclosure.

FIGS. 16A, 16B, 16C, 16D, 16E, and 16F schematically illustrate example tap cells according to embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins

TAP cells, also referred as well tap cells, pick-up tap cells, tap structures, are included in integrate circuit (IC) layout diagrams to improve latch-up immunity of ICs. A tap cell may be a standard cell which defines a region in a doped well where the doped well is coupled to a bias voltage, such as a power supply voltage. In the state-of-the-art technology, a tap cell is built similar to a transistor with active regions formed over the doped well and a gate structure formed across the active regions.

With the current tendency of scaling down semiconductor devices, placement of TAP cells in an IC layout diagram for manufacturing ICs raises one or more considerations including, but not limited to, process bottleneck due to reduced lithography critical dimension (CD), and mixed channel effects. To address one or more of such considerations, embodiments of the present disclosure provide a tap cell without gate structures. Particularly, a tap cell according to embodiments of the present disclosure may include a semiconductor fin structure and an epitaxial crown grown from the semiconductor fin structure. Because the tap cell does not include any gate structures, design layout with such tap cells may have a reduced size by avoiding design rules for gate pitches in directions along and across the fin structures. In some embodiments, circuit layouts with the tap cells according to the present disclosure my reduce circuit area between about 7% and 15%, As a result, with the tap cells according to, it is possible to achieve one or more effects, including, but not limited to, relaxing process constraints, increasing latch-up immunity at reduced well tap areas, reducing well tap resistance, and improving tap current collection efficiency.

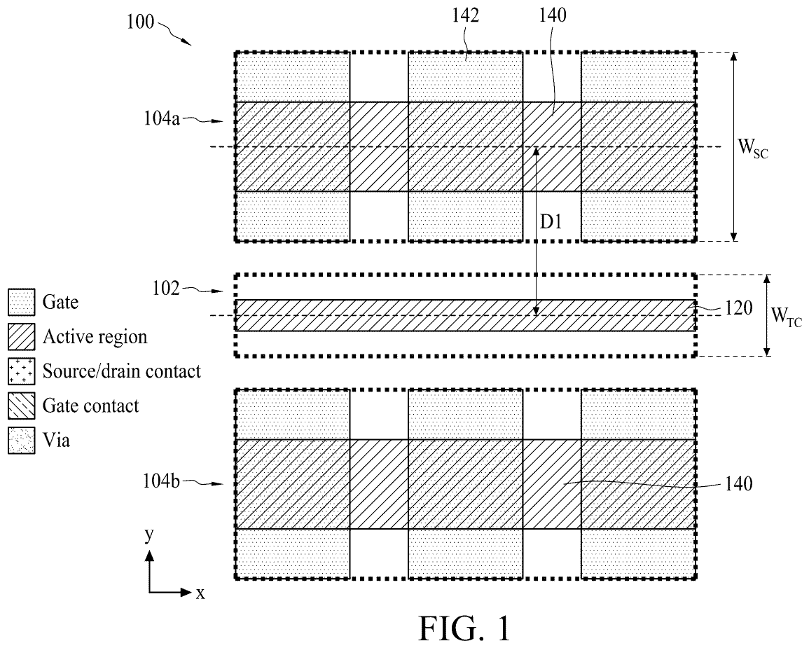

FIG. 1 is a diagram of a layout design 100 including a tap cell 102 according to embodiments of the present disclosure. The layout design 100 may be a portion of an integrated circuit. The layout design 100 includes two transistors 104a, 104b. The tap cell 102 is disposed between the transistors 104a, 104b. The transistors 104a, 104b may include an active region 140 along the x-direction and gate structures 142 along the y-direction. In some embodiments, the transistors 104a, 104b may be FinFET devices, the active region 140 may include one or more semiconductor fins and epitaxial grown source/drain regions. The gate structures 142 may include a gate dielectric layer and a gate electrode layer formed around the semiconductor fin. The tap cell 102 includes an active region 120 along the same direction as the same direction as the active region 140 of the transistors 104a, 104b. In some embodiments, the active region 120 may include one or more semiconductor fins along the x-direction and epitaxial regions grown from the one or more semiconductor fins. The tap cell 102 does not include any gate structure across the active region 120. The active region 120 of the tap cell 102 may be connected to conductive vias and lines along the x-direction, forming a conductive wall between the transistors 104a, 104b. The conductive wall blocks interference between the transistors 104a, 104b.

The active region 120 of the tap cell 102 may be further connected to a power rail, thereby, provide in a reduction in the substrate resistance, and the reduction in the undesirable positive feedback in the integrated circuit. For example, when the active region 120 is a n-well region, the active region 120 may be coupled to VDD power rails. Coupling the active region 120 to power rails body bias to the transistors 104a, 104b and prevent undesirable latch-up from parasitic bipolar transistors of integrated circuits. Through the tap cell 102, n-well regions of the transistors 104a, 104b are coupled to VDD power rails, and p-well regions or p-type substrates are coupled to VSS power rails, which are electrical ground. Coupling the well regions and substrate regions to the VDD power rails and VSS power rails, respectively, may result in a reduction in the substrate resistance, and the reduction in the undesirable positive feedback in the integrated circuit.

In the state-of-art technologies, dummy gate electrodes (dummy polysilicon lines) are added in the tap cells to achieve process uniformity. However, the dummy gate electrodes in the tap cells adversely increase chip area usage of the tap cells. By omitting gate structures in the tap cell 102, the chip area is reduced. As shown in FIG. 1, the tap cell 102 ay have a cell width Wtc along the y-direction. In some embodiments, a ratio of the cell width Wtc over the cell width Wsc is in a range between about 0.2 and about 0.8.

Conductive layers and dielectric materials are not shown in the layout design 100 for clarity. Additional details are further described with the figures below.

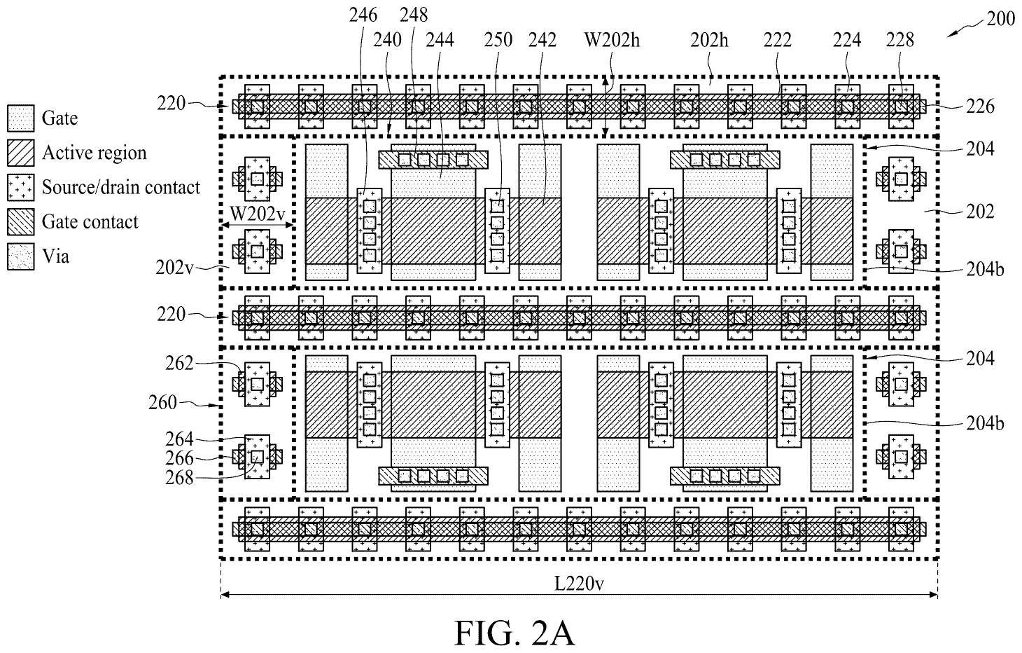

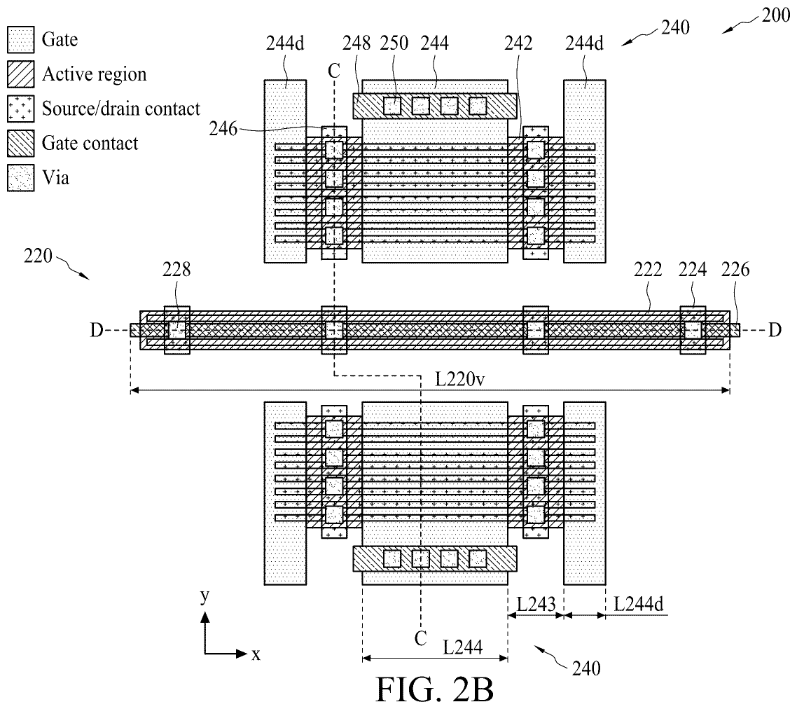

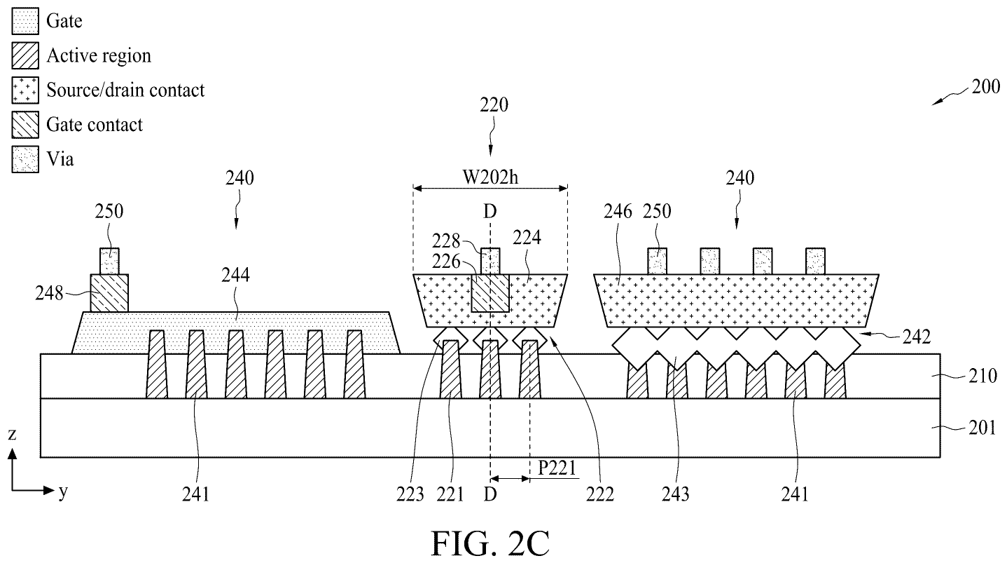

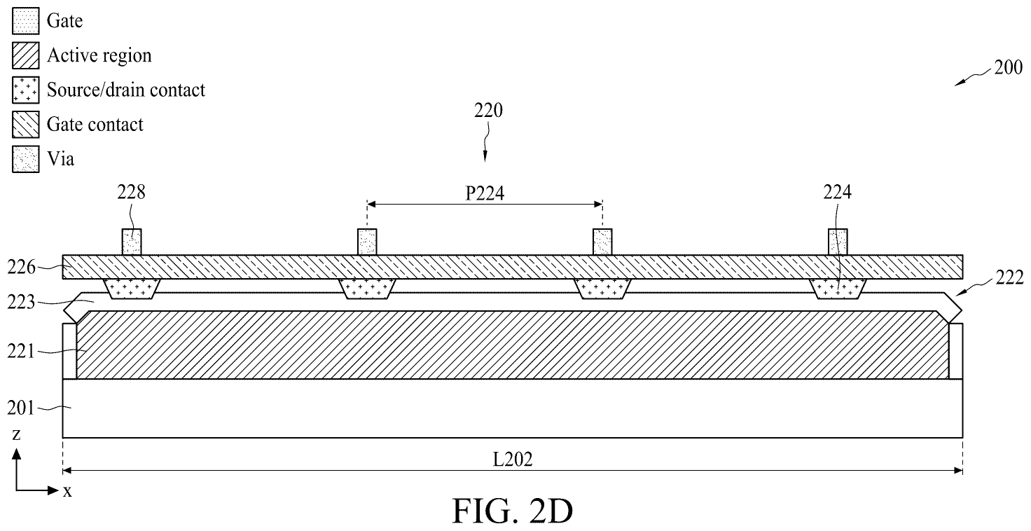

FIG. 2A is a diagram of an integrated circuit layout 200 including tap cells according to embodiments of the present disclosure. FIG. 2B is a partial enlarged view of the integrated circuit layout 200 of FIG. 2A. FIGS. 2C and 2D are cross sectional views of the integrated circuit layout 200 along C-C and D-D lines in FIG. 2B respectively.

The integrated circuit layout 200 may be a portion of an integrated circuit, such as an image signal processer. An image signal processer may include columns of ADC (analog digital converter), logic circuits, and DAC (digital analog converter). In FIG. 2A, the integrated design 200 includes function cells 204 arranged in rows and columns.

Each functional cell 204 may be a standard cell configured to perform certain function or a portion of a standard cell. In the example of FIGS. 2A-2D, the functional cell 204 includes two transistors 240. In some embodiments, the functional cell 204 may be a cell within an ADC circuit. The transistors 240 may be FinFET transistors, planar transistors, or GAA transistors. In FIGS. 2A-2D, the transistors 240 are FinFET transistors formed on fin structures 241 formed along the x-direction. In some embodiments, the transistors 240 are disposed side by side along the x-direction. The transistors 240 may include active region 240 along the x-direction and gate structures 244 along the y-direction. In some embodiments, the transistors 240 may be FinFET devices, the active region 242 may include one or more semiconductor fins and epitaxial grown source/drain regions. The gate structures 244 may include a gate dielectric layer and a gate electrode layer formed around the semiconductor fin. Conductive features, such as source/drain contacts 246, gate contacts 248, and contact vias 250, formed over the active regions 240 and the gate structures 244.

The transistors 240 are disposed within a cell boundary 204b, which defines a cell region. In some embodiments, the integrated circuit layout 200 includes a tap region 202 around the cell boundary 204b. The tap region 202 may be a belt shaped region along the cell boundary 204b. The tap region 202 may include horizontal sections 202h along the x-direction and vertical sections 202v along the y-direction. The horizontal section 202h is shared between two functional cells 204 arranged in a column along the y-direction, as shown in FIG. 2A. The vertical section 202h is shared between two functional cells 204 arranged in a row along the x-direction (not shown here). The horizontal section 202h of the tap region 202 may have a width W202h and the vertical section 202v of the tap region 202 may have a width W202v. The width W202h and width W202v may be the same or different. In some embodiments, the tap region 202 is free of gate structures. The width W202h and width W202v may be selected to be sufficient for forming tap cells or tap structures without gate structure.

In some embodiments, tap cells 220 are formed in the horizontal sections 202h of the tap region 202. In some embodiments, a single tap cell 220 is formed in an individual horizontal section 202h. The tap cell 220 has a length L220 along the x-direction. In some embodiments, the length L220 may be in a range between about 100 nm and about 600000 nm. The tap cell 220 is configured to block noise between the functional cells 204 on opposite sides of the horizontal sections 202h of the tap region 202. The tap cell 220 may include a continuous conductive structure, which prevents electric signals from one side of the tap cell 220 across to the other side of the tap cell 220. In some embodiments, the tap cell 220 may include an active region 222 disposed along the x-direction. The active region 222 may extend substantially the entire length of the tap cell 220 along the x direction. The active region 222 may include a semiconductor fin structure extended along the x-direction and an epitaxial material grown from the semiconductor fin structure. Contact features 224, 226, 228 are subsequently formed over the active region 222.

In some embodiments, dummy tap cells 260 are formed in the vertical sections 202v of the tap region 202. In some embodiments, one or more dummy tap cells 260 is formed in an individual vertical section 202v. The one or more dummy tap cells 260 may be arranged in a column along the y-direction. The dummy tap cells 260 may be formed to provide pattern density balance. In other embodiments, the dummy tap cells 260 may block a portion of noise between the functional cells 204 on opposite sides of the vertical sections 202v of the tap region 202. In other embodiments, the dummy tap cells 260 may be used to connect a substrate or active region to a power rail. Each dummy tap cell 260 may include a column-like conductive structure. In some embodiments, the dummy tap cell 260 may include an active region 262 disposed along the x-direction. The active region 262 may extend substantially the width length of the vertical section 202v of the tap region 202. The active region 262 may include a semiconductor fin structure extended along the x-direction and an epitaxial material grown from the semiconductor fin structure. Conductive features 264, 266, 268 are subsequently formed over the active region 262.

FIGS. 2B-2D schematically demonstrate details of the tap cells 220 according to some embodiments of the present disclosure. As shown in FIGS. 2B and 2C, the transistors 240 are FinFET transistors. The active region 242 includes multiple fin structures 241 and source/drain regions 243. In some embodiments, the number of fin structures 241 may be in a range between 1 and about 20. The fin structures 241 are formed over a substrate 201 along the x-direction. An isolation region 210 is formed around a lower portion of the fin structure 241. The gate structure 244 may have a gate length L244 along the x-direction. The gate length L244 may be selected according to the function of the transistor 240. For example, a long gate length L244 may be selected for the transistor 240 when the transistor 240 is a high voltage transistor while a short gate length L244 may be selected for the transistor 240 when the transistor 240 is a low voltage transistor. In some embodiments, the gate length L244 may be in a range between about 16 nm and about 12000 nm.

The gate structure 244 is formed across a middle portion of the multiple fin structures 241. The fin structures 241 extend beyond the gate structure 244 in the x-direction. The source/drain regions 243 are formed the fin structures 241 extending out of the gate structure 244. In some embodiments, dummy gate structures 244d are formed over end portions of the fin structures 241. The dummy gate structures 244d provide physical boarders for the source/drain regions 243, enabling the source/drain regions 243 to grow sufficient volume and desirable shapes. The dummy gate structure 244d may have a gate length L244d along the x-direction. The gate length L244d may be selected according to the design rules and the wavelengths of the patterning tool. In some embodiments, the gate length L244d may be in a range between about 16 nm and about 240 nm. In some embodiments, a distance between the dummy gate structures L244d and the gate structure 244 define a source/drain length L243.

The tap cell 220 is disposed between the transistors 240 along the x-direction forming a conductive wall between the transistors 240. As shown in FIGS. 2B-2C, the active region 222 of the tap cell 220 may include one or more fin structures 221 extending along the x-direction and epitaxial crowns 223 grown from the two or more fin structures 221. The fin structures 221 are parallel to the fin structures 241 of the transistor 240. In some embodiments, the fin structures 221 and the fin structures 241 may be formed at the same time and have the same pitch. In other embodiments, the fin structures 221 may have a pitch lower than the fin structures 241. The fin structures 221 has a pitch P221. In some embodiments, the pitch P221 of the fin structures 221 may is a range between about 14 nm and about 32 nm. In some embodiments, the tap cell 220 may include multiple fin structures to obtain enough conductive volume. In some embodiments, the number of fin structures 221 may be in a range between 1 and 4, for example 3.

The epitaxial crowns 223 are grown from the fin structures 221 above the isolation region 210. In some embodiments, the epitaxial crowns 223 in the tap cells 220 and the source/drain regions 243 of the transistors 240 are formed in different epitaxial deposition processes. In some embodiments, the epitaxial crowns 223 in the tap cells 220 may be formed at the same time with the source/drain regions 243 of the transistors 240.

Because there are no gate structures across the fin structures 221, the epitaxial crown 223 may have a smaller volume than the source/drain regions 243. In some embodiments, the source/drain region 243 may be a merged volume from epitaxial growth of the multiple fin structures 241 while the epitaxial crowns 223 grown from different fin structures 221 remain separated from each other.

In some embodiments, after formation of the epitaxial crown 223, the fin structures 221 remain above a top surface 210t of the isolation region 210. The epitaxial crown 223 may grow from a top portion of the fin structures 221. For example, the epitaxial crowns 223 may grow from top surfaces and sidewalls of the fin structures 221. In some embodiments, the epitaxial crowns 223 in the tap cells 220 may be higher than the source/drain regions 243 in the transistors 240.

As shown in FIG. 2D, the fin structure 221 extends almost the entire length L202 of the tap cell 220. The epitaxial crown 223 also extends along the length L202 of the tap cell 220. Each fin structure 221 and the corresponding epitaxial crown 223 form a continuous conductive body. In some embodiments, the active region 222 may include two or more continuous conductive bodies separated by dielectric materials, such as contact etch stop layer and interlayer dielectric layer (omitted from FIGS. 2A-2D for clarity).

In some embodiments, one or more tap contact features 224 are formed on the active region 222. The tap contact features 224 may be formed during the same process as the source/drain contact features 246. In some embodiments, the tap contact features 224, like the source/drain contact features 246, may be formed along the y-direction. In some embodiments, the tap contact features 224 extend across the one or more fin structures 221 and the epitaxial crowns 223, and electrically connecting the one or more fin structures 221 and the epitaxial crowns 223.

In some embodiments, two or more tap contact features 224 may be distributed along the active region 222 depending on the tap cell length L202 and pattern density of the source/drain regions 243. In some embodiments, the tap contact features 224 has a pitch P224 along the x-direction. In some embodiments, the pitch P224 may be selected according to the gate length L244 of the gate structures 244 in the transistors. In some embodiments, the pitch P224 is greater than the gate length L244. In some embodiments, the pitch P224 is a total of the gate length L244 and the source/drain length L243.

In some embodiments, a tap line 226 is formed above the active region 222 electrically connecting the two or more tap contact features 224. The tap line 226 extends along the entire length of the active region 222. As shown in FIGS. 2C and 2D, the tap line 226 and the tap contact features 224 effectively form a conductive wall with the active region 222. In some embodiments, the tap line 226 and the gate contact features 248 of the transistors 240 may be patterned and formed in the same process. In some embodiments, the gate contact features 248 may be conductive lines formed along the x-direction.

In some embodiments, conductive vias 228 may be formed over the tap line 226 to connect with subsequent conductive layers, for example, an interconnect structure. In some embodiments, the conductive vias 228 may align with the tap contact features 224. The conductive vias 228 may be formed during the same process with the conductive vias 248 over the transistors 240.

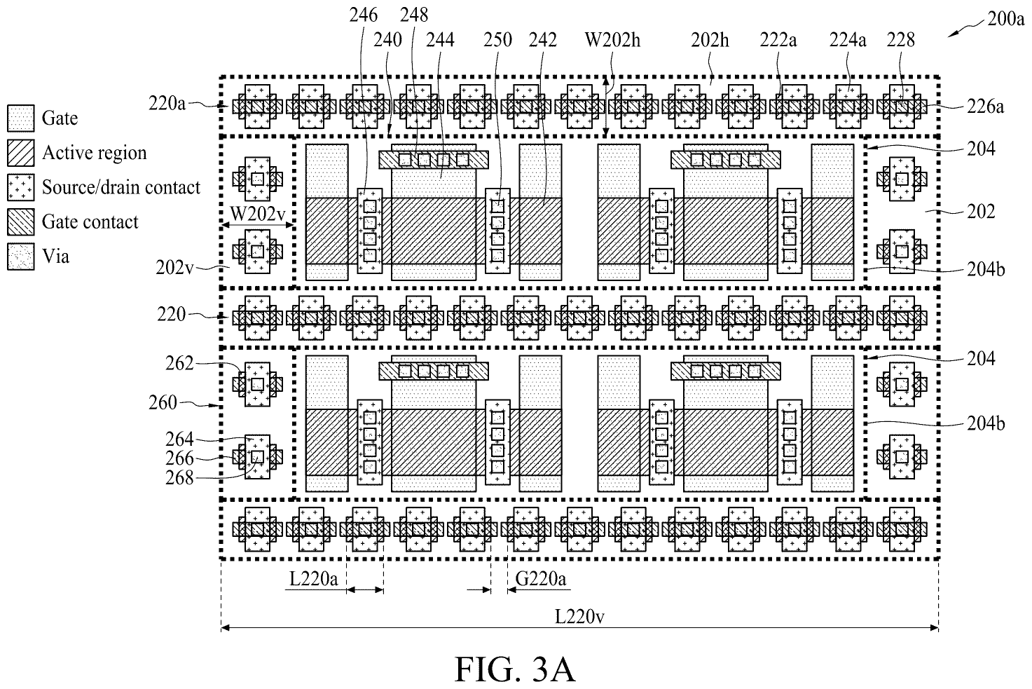

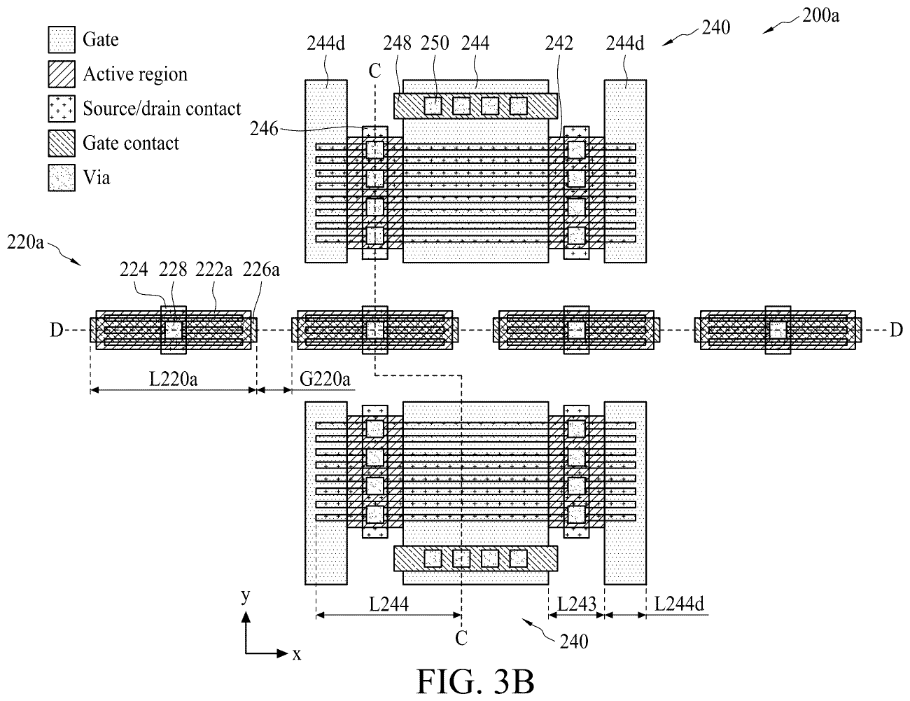

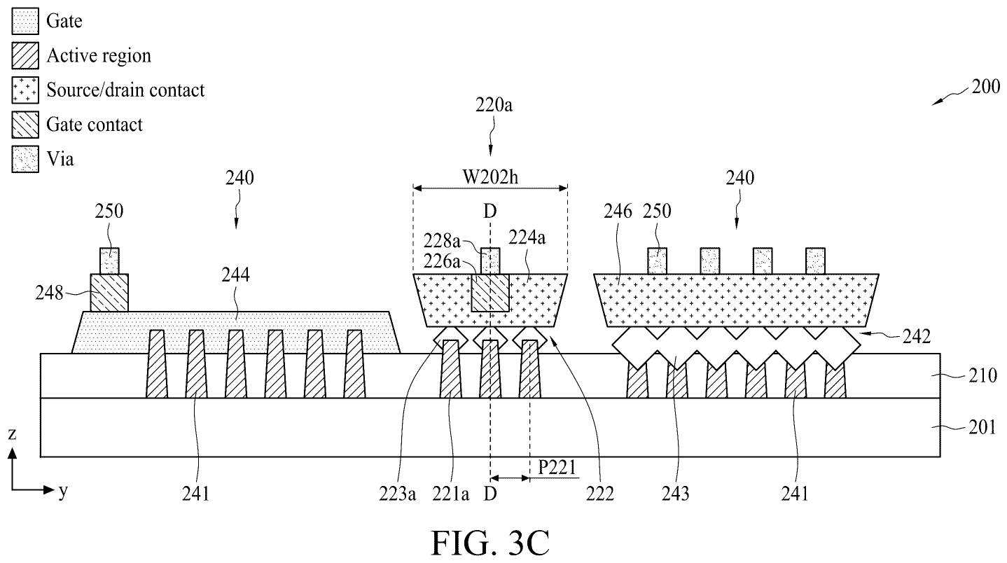

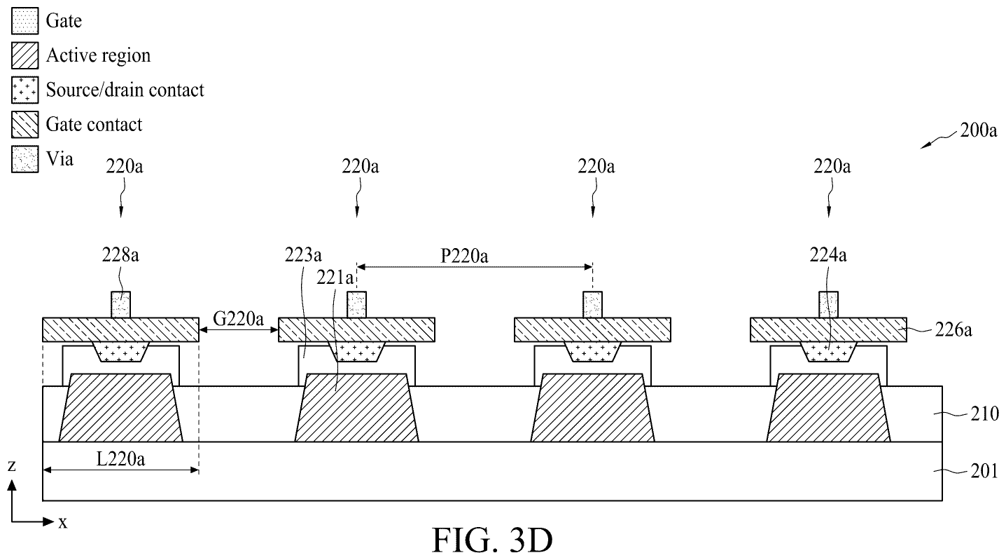

FIG. 3A is a diagram of an integrated circuit layout 200a including tap cells according to embodiments of the present disclosure. FIG. 3B is a partial enlarged view of the integrated circuit layout 200a of FIG. 3A. FIGS. 3C and 3D are cross sectional views of the integrated circuit layout 200a along C-C and D-D lines in FIG. 3B respectively. The integrated circuit layout 200a is similar to the integrated circuit layout 200 except that the integrated circuit layout 200a includes two or more tap cells 220a disposed between the two transistors 240 instead of one long continuous tap cell 220.

The tap cells 220a are similar to the tap cell 220 except that the tap cells 220a are shorter along the x-direction than the tap cell 220. In some embodiments, the two or more tap cells 220a may be disposed along the x-direction with a gap G220a between neighboring tap cells 220a. As shown in FIGS. 3A, a plurality of tap cells 220a are disposed between the transistors 240, forming a substantively conductive wall between the transistors 240. As shown in FIGS. 3B-3C, each tap cell 220a includes an active region 222a. The active region 222a may include one or more fin structures 221 a extending along the x-direction and epitaxial crowns 223a grown from the two or more fin structures 221a. The fin structures 221a are parallel to the fin structures 241 of the transistors 240. In some embodiments, the fin structures 221a and the fin structures 241 may be formed at the same time and have the same pitch. In some embodiments, the tap cell 220 may include multiple fin structures to obtain enough conductive volume. In some embodiments, the number of fin structures 221 may be in a range between 1 and 4, for example 3.

The epitaxial crowns 223a are grown from the fin structures 221a above the isolation region 210. In some embodiments, the epitaxial crowns 223a may be formed simultaneously with the source/drain regions 243. Without support from the gate structures across the fin structures 221a, the epitaxial crown 223a may have a smaller volume than the source/drain regions 243 formed at the same time. By keeping the fin structures 221a short along the x-direction, the epitaxial grown 223a may grow fuller, thereby, increasing volume. As shown in FIGS. 3A and 3D, multiple tap cells 220a are distributed along the x-direction to cover the length L202 of the tap region 202. In some embodiments, each of the tap cells 220a has a cell length L220a along the x-direction. Neighboring tap cells 220a have a gap G220a. The cell length L220a and the gap G220a may be selected according to design rules. In some embodiments, the gap G220a may be in a range between about 1 nm and about 20 nm. The cell length L220a may be in a range between about 20 nm and about 12000 nm. In some embodiments, the tap cells 220a are arranged in a cell pitch P220a. In some embodiments, the cell pitch P220 may be similar to the pitch of the source/drain regions 243 in the transistors 240.

The tap cells 220a may include one or more tap contact features 224a formed on the active region 222. In some embodiments, one tap contact feature 224a is formed in near a center region of the tap cell 220a. The tap contact features 224a may be formed during the same process as the source/drain contact features 246. In some embodiments, the tap contact features 224a, like the source/drain contact features 246, may be formed along the y-direction. In some embodiments, the tap contact features 224a extend across the one or more fin structures 221a and the epitaxial crowns 223a, and electrically connecting the one or more fin structures 221 and the epitaxial crowns 223a.

In some embodiments, a tap line 226a is formed above the active region 222 in contact with the tap contact features 224a. The tap line 226a extends along the entire length of the active region 222a. The tap line 226a and the tap contact feature 224a effectively form a conductive wall with the active region 222a.

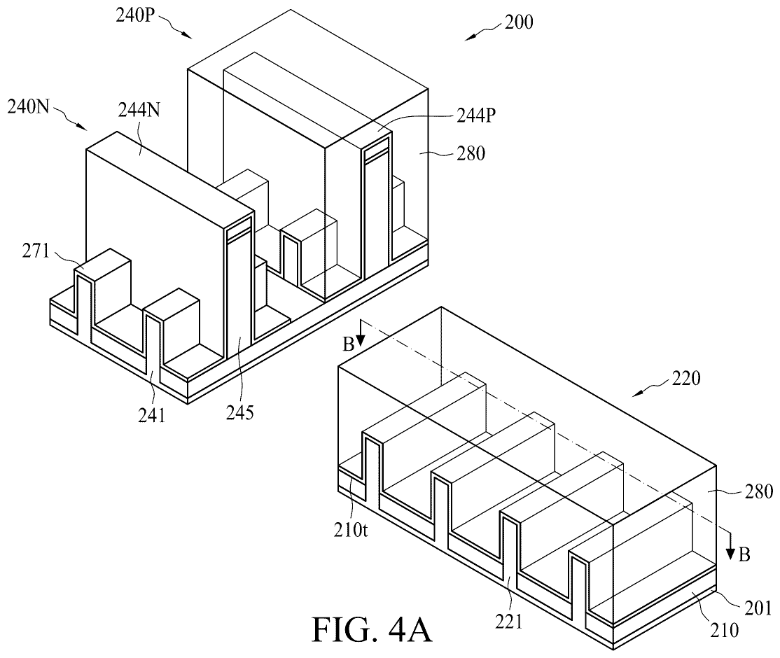

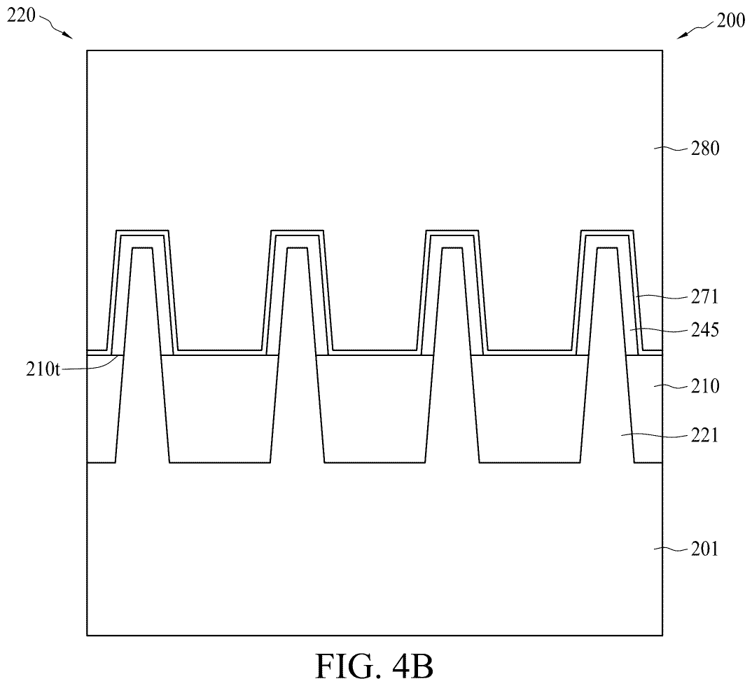

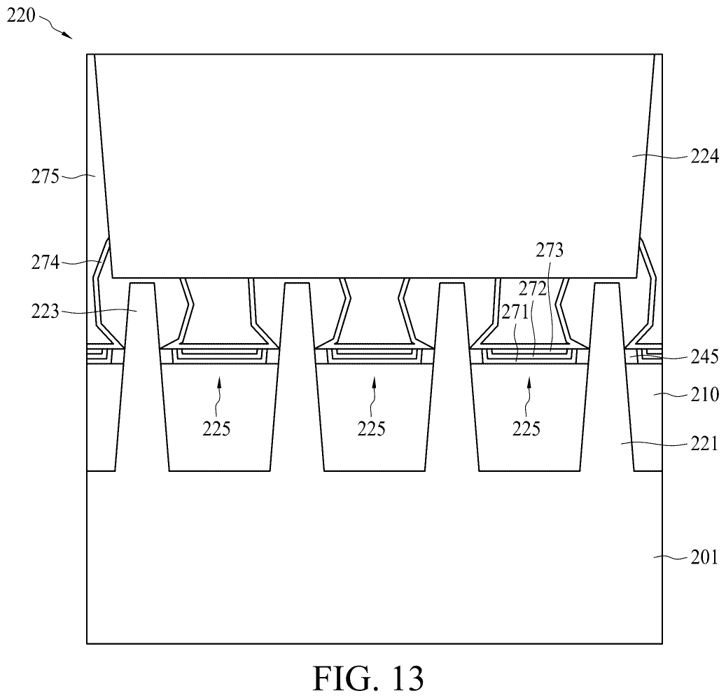

As discussed above, the tap cells 220, 220a may be fabricated with functional cells on the same substrate. FIGS. 4A-4B, 5A-5B, 6A-6B, 7A-7B, 8A-8B, 9A-9B, 10A-10B, 11A-11B, 12, 13, and 14A-14D schematically demonstrate various stages of forming an integrated circuit including tap cells according to the present disclosure.

FIG. 4A is a schematic perspective view of a portion of the integrated circuit 200 after formation of the fin structures 221 for the tap cell 220 and fin structures 241 for the transistors 240. The gate structures 244 are formed across fin structures 241. FIG. 4B is a schematic cross sectional view of the fin structures 221 for the tap cell 220.

As shown in FIGS. 4A and 4B, the fin structures 221 and 241 are formed on the substrate 201. The substrate 201 may be a silicon substrate. Alternatively, the substrate 201 may comprise another elementary semiconductor, such as germanium; a compound semiconductor including IV-IV compound semiconductors such as SiC and SiGe, III-V compound semiconductors such as GaAs, GaP, GaN, InP, InAs, InSb, GaAsP, AlGaN, AlInAs, AlGaAs, GaInAs, GaInP, and/or GaInAsP; or combinations thereof.

In some embodiments, the substrate 201 includes a crystalline silicon substrate (e.g., wafer). A p-type substrate or n-type substrate may be used and the substrate 201 may include various doped regions, depending on design requirements. In some embodiments, the doped regions may be doped with p-type or n-type dopants. For example, the doped regions may be doped with p-type dopants, such as boron or BF₂; n-type dopants, such as phosphorus or arsenic; and/or combinations thereof. The doped regions may be configured for an n-type FinFET, or alternatively configured for a p-type FinFET. In some alternative embodiments, the substrate 201 may be made of some other suitable elemental semiconductor, such as diamond or germanium; a suitable compound semiconductor, such as gallium arsenide, silicon carbide, indium arsenide, or indium phosphide; or a suitable alloy semiconductor, such as silicon germanium carbide, gallium arsenic phosphide, or gallium indium phosphide. Also alternatively, the substrate may include an epitaxial layer. For example, the substrate may have an epitaxial layer overlying a bulk semiconductor. Further, the substrate may be strained for performance enhancement. For example, the epitaxial layer may include a semiconductor material different from that of the bulk semiconductor, such as a layer of silicon germanium overlying bulk silicon or a layer of silicon overlying bulk silicon germanium. Such strained substrates may be formed by selective epitaxial growth (SEG). Furthermore, the substrate may include a semiconductor-on-insulator (SOI) structure. Also alternatively, the substrate may include a buried dielectric layer, such as a buried oxide (BOX) layer, such as that formed by separation by implantation of oxygen (SIMOX) technology, wafer bonding, SEG, or other appropriate process.

The fin structures 221, 241 are disposed over the substrate 201. The fin structures 221, 241 may be made of the same material as the substrate 201 and may continuously extend from the substrate 201. In this embodiment, the fin structures 221, 241 are made of silicon (Si). The silicon layer of the fin structures 221, 241 may be intrinsic, or appropriately doped with an n-type impurity or a p-type impurity. The fin structures 221, 241 may be formed by suitable patterning and etching processes.

After formation of the fin structures 221, 241, the isolation region 210 is formed on the substrate 201 and around lower portions of the fin structures 221, 241. The isolation region 210 may be formed by a high density plasma chemical vapor deposition (HDP-CVD), a flowable CVD (FCVD), or other suitable deposition process and followed by an etch back process. In some embodiments, a dielectric material may be formed conformally to cover the fin structures 221, 241 by a suitable deposition process, such as atomic layer deposition (ALD). In some embodiments, the dielectric material may include silicon oxide, silicon nitride, silicon oxynitride, fluorine-doped silicate glass (FSG), a low-k dielectric, combinations thereof. The dielectric material is recess etched using a suitable anisotropic etching process to expose the fin structures 221, 241. As shown in FIG. 4A, the fin structures 221, 241 extend above a top surface 210t of the isolation region 210.

The gate structures 244 are then formed over the fin structures 231. In some embodiments, the gate structures 244 may be sacrificial gate structures. The gate structures 240 are formed over a portion of the fin structure 241 which are to be channel regions. In some embodiments, the gate structures 244 may include a sacrificial gate dielectric layer, a sacrificial gate electrode layer, a pad layer, and a mask layer.

The sacrificial gate dielectric layer may be formed by a blanket deposition over the fin structures 221, 241, and the isolation region 210. The sacrificial gate dielectric layer includes one or more layers of insulating material, such as a silicon oxide-based material. In some embodiments, silicon oxide formed by CVD is used. In some embodiments, the sacrificial gate dielectric layer has a thickness in a range between about 1 nm and about 5 nm.

The sacrificial gate electrode layer is then blanket deposited on the sacrificial gate dielectric layer. The sacrificial gate electrode layer includes silicon such as polycrystalline silicon or amorphous silicon. The thickness of the sacrificial gate electrode layer is in a range between about 100 nm and about 200 nm. In some embodiments, the sacrificial gate electrode layer is subjected to a planarization operation. The sacrificial gate electrode layer may be deposited using CVD, including LPCVD and PECVD, PVD, ALD, or other suitable processes.

Subsequently, the pad layer and the mask layer are formed over the sacrificial gate electrode layer. The pad layer may include silicon nitride. The mask layer may include silicon oxide. Next, a patterning operation is performed on the mask layer, the pad layer, the sacrificial gate electrode layer, and the sacrificial gate dielectric layer to form the gate structures 240.

After the gate structures 240 are formed, sidewall spacer layer 245 are subsequently formed on sidewalls of the gate structures 244 and the fin structures 221, 241. In some embodiments, the sidewall spacer layer 245 is formed by blanket deposition of an insulating material followed by anisotropic etch to remove insulating material from horizontal surfaces. The sidewall spacer layer 245 may have a thickness in a range between about 2 nm and about 10 nm. The sidewall spacer layers 245 may include one or more a silicon nitride-based material, such as SiN, SiON, SiOCN or SiCN and combinations thereof.

After formation of the sidewall spacer layer 245, a mask layer 271 is disposed over the fin structures 241, 221, and the gate structures 240. In some embodiments, the mask layer 271 may be deposited by ALD or other suitable process. The mask layer 271 may be patterned to protect selected areas during subsequent epitaxial processes. The mask layer 271 may include a low k dielectric material, for example dielectric material with a k value in a range between about 5 and about 8. In some embodiments, the mask layer 271 includes SiOCN with a thickness about 50 A.

As shown in FIGS. 4A and 4B, a photoresist layer 280 is deposited and patterned to expose areas for subsequent source/drain formation. In the example of FIGS. 4A and 4B, areas of n-type devices are exposed. Other areas, including the tap cells 220 and the p-type device areas, are covered by the photoresist layer 280.

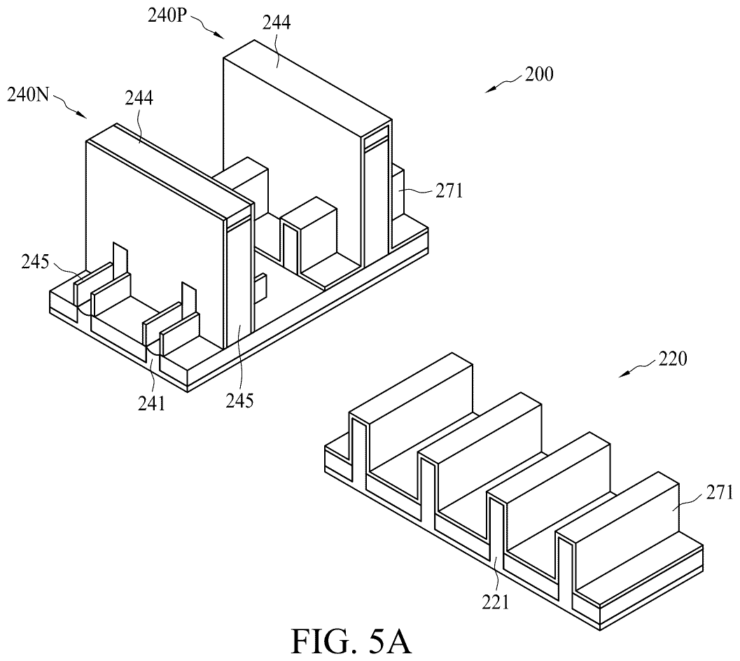

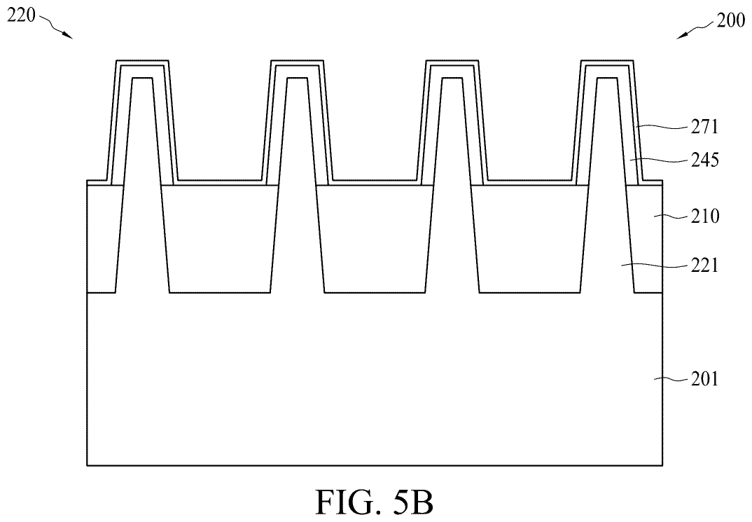

After patterning the photoresist layer 280, the mask layer 271 exposed by the photoresist layer 280 is removed, the fin structures 241 in the n-type device are exposed. An etch back process is performed to remove the exposed fin structures 241. In some embodiments, the fin structures 241 are recessed to a level below the top surface 210t of the isolation region 210 and form source/drain recesses above. The photoresist layer 280 is then removed, as shown in FIGS. 5A-5B. FIG. 5A is a schematic perspective view of a portion of the integrated circuit 200 after the etch back process and removal of the photoresist layer. FIG. 5B is a cross sectional view of the fin structures 221 for the tap cell 220.

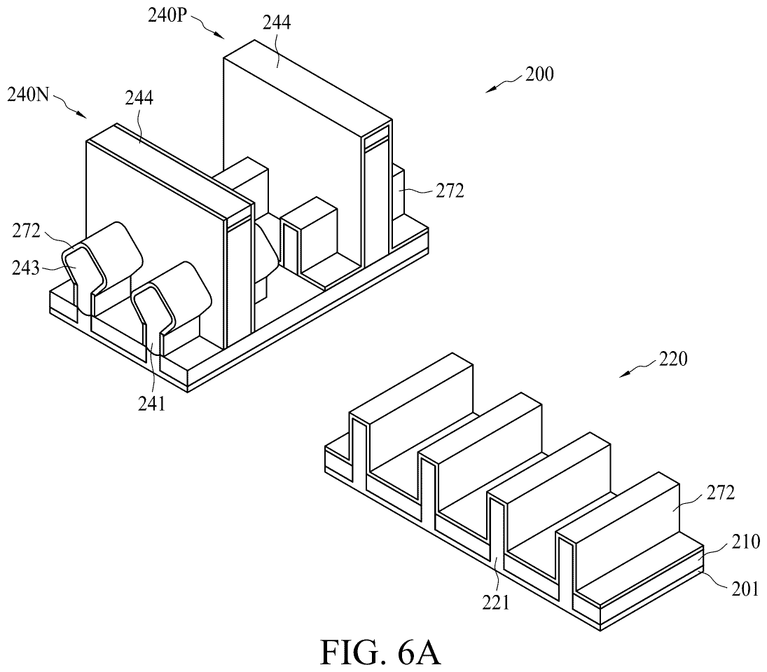

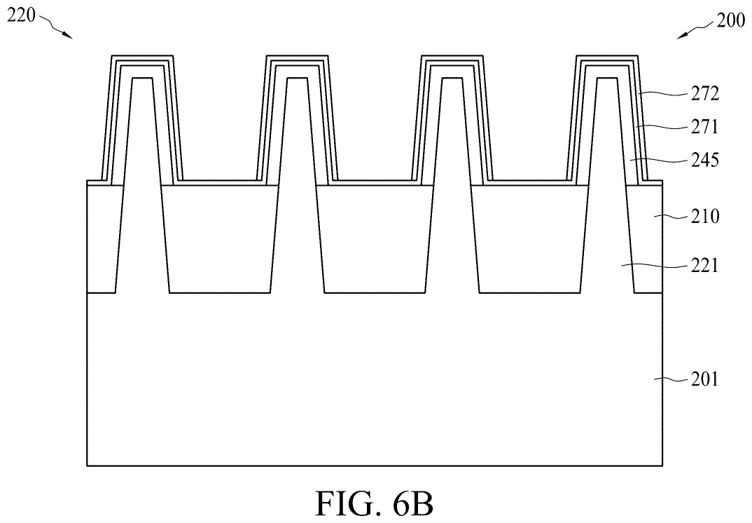

As shown in FIGS. 5A and 5B, the mask layer 271 covers the semiconductor materials in the fin structures 221 in the tap cell 220 and the fin structures 241 in the p-type device area. The source/drain regions 243 for the n-type devices are grown from exposed semiconductor surfaces of the fin structures 241. As shown in FIG. 6A, the epitaxial source/drain regions 243 for the n-type devices are formed. The epitaxial source/drain regions 243 for the n-type device may include one or more layers of Si, SiP, SiC and SiCP with n-type dopants.

A mask layer 272 is then deposited over the source/drain regions 243 for the n-type devices, the fin structures 241 for the p-type devices, the fin structures 221 for the tap cells 220, and the gate structures 240. In some embodiments, the mask layer 272 may be deposited by ALD or other suitable process. The mask layer 272 may be patterned to protect selected areas during subsequent epitaxial processes. The mask layer 272 may include a low k dielectric material, for example dielectric material with a k value in a range between about 5 and about 8. In some embodiments, the mask layer 272 includes SiOCN with a thickness about 50 A. After this operation, the fin structures 221 in the tap cell 220 are covered by the mask layers 271 and 272.

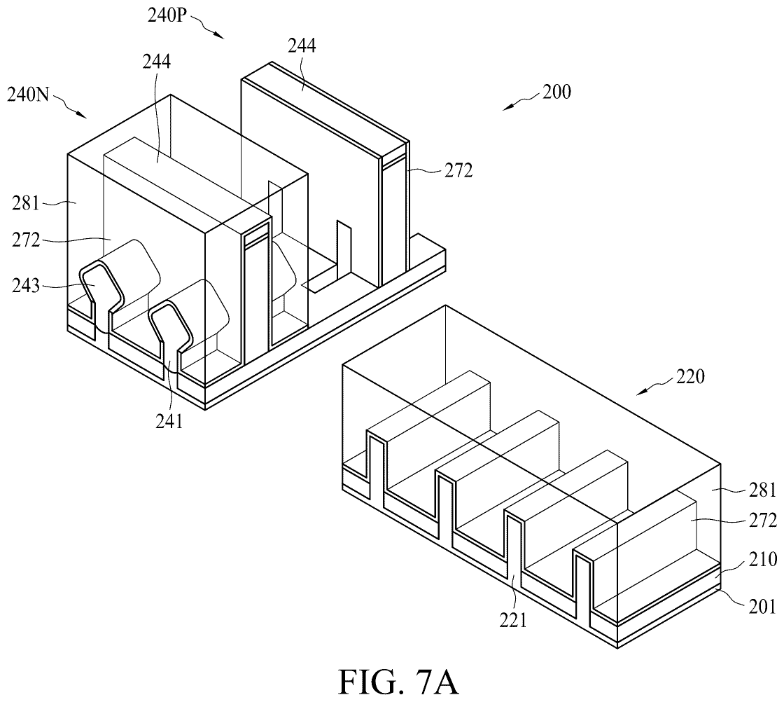

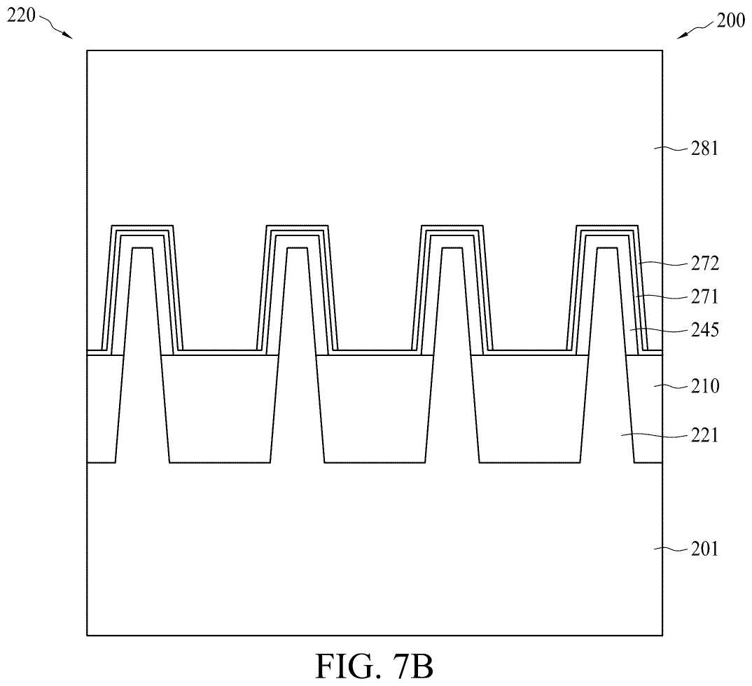

As shown in FIGS. 7A and 7B, a photoresist layer 281 is deposited and patterned to expose areas for subsequent source/drain formation. In the example of FIGS. 7A and 7B, areas of p-type devices are exposed. Other areas, including the tap cells 220 and the n-type device areas, are covered by the photoresist layer 281.

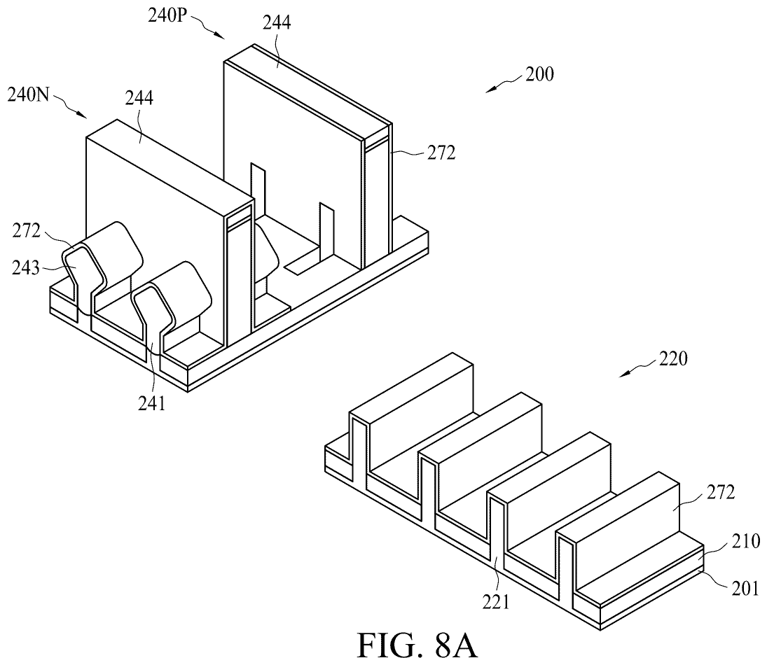

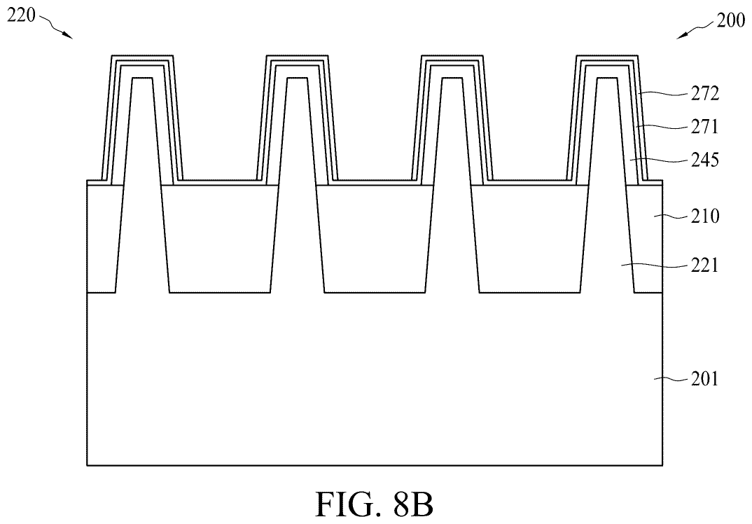

After patterning the photoresist layer 281, the mask layer 272 exposed by the photoresist layer 281 is removed, the fin structures 241 in the p-type device are exposed. An etch back process is performed to remove the exposed fin structures 241. In some embodiments, the fin structures 241 are recessed to a level below the top surface 210t of the isolation region 210 and form source/drain recesses above. The photoresist layer 281 is then removed, as shown in FIGS. 8A-8B.

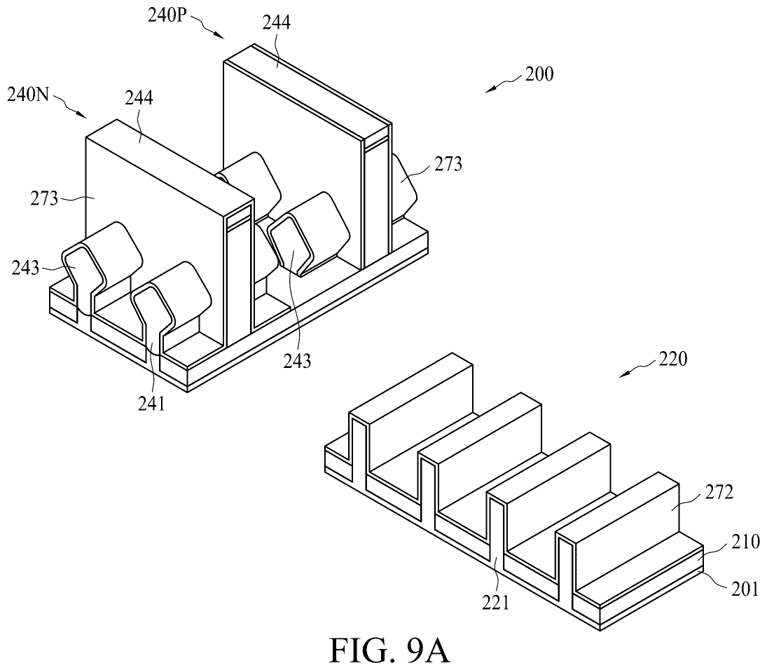

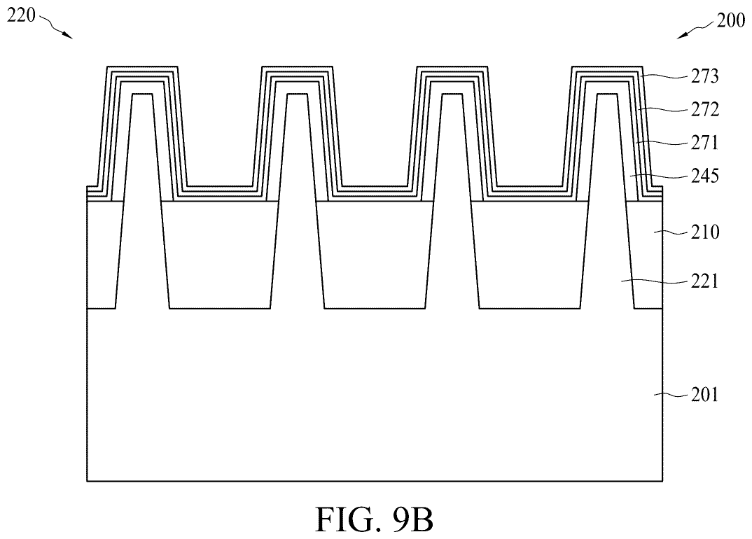

As shown in FIGS. 8A and 8B, the mask layer 272 covers the semiconductor materials in the fin structures 221 in the tap cell 220 and the source/drain regions 243 in the n-type device area. The source/drain regions 243 for the p-type devices are grown from exposed semiconductor surfaces of the fin structures 241. As shown in FIG. 9A, the epitaxial source/drain regions 243 for the p-type devices are formed. In some embodiments, the epitaxial source/drain regions 243 for the p-type device may include one or more layers of Si, SiGe, Ge, and a p-type dopants.

A mask layer 273 is then deposited over the source/drain regions 243 for the n-type devices, the source/drain regions 243 for the p-type devices, the fin structures 221 for the tap cells 220, and the gate structures 240. In some embodiments, the mask layer 273 may be deposited by ALD or other suitable process. The mask layer 273 may be patterned to protect selected areas during subsequent epitaxial processes. The mask layer 273 may include a suitable dielectric material, for example silicon nitride containing material. In some embodiments, the mask layer 273 includes SiN with a thickness about 50 A. As shown in FIG. 9B, the fin structures 221 are covered by three mask layers 271, 272, 273.

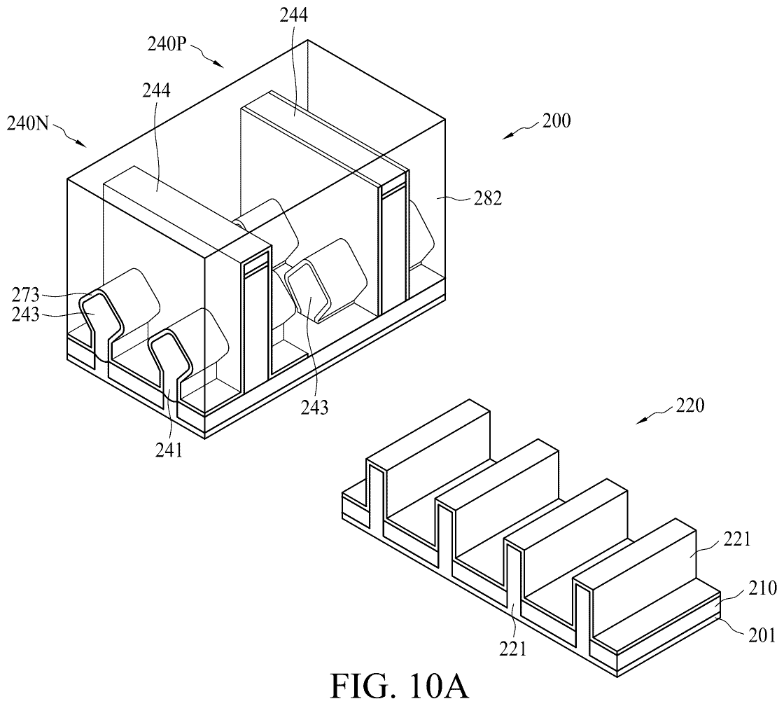

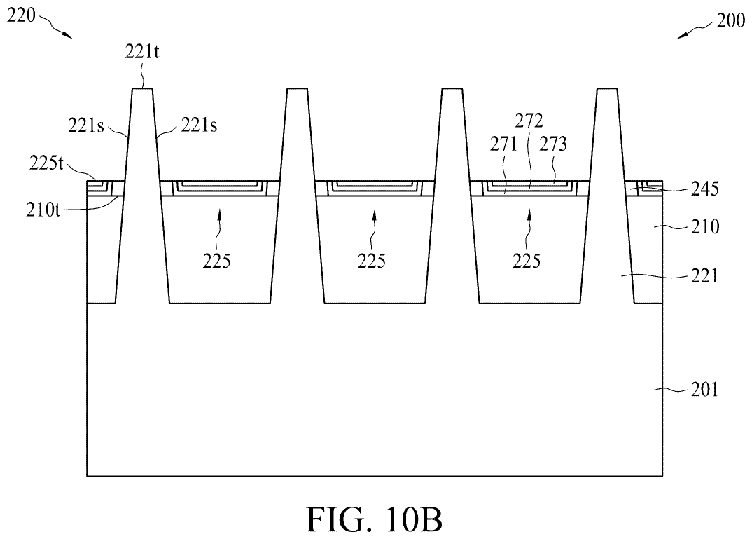

As shown in FIGS. 10A and 10B, a photoresist layer 282 is deposited and patterned to expose areas of the tap cells 220. Other areas, including areas for the n-type devices and p-type devices, are covered by the photoresist layer 282.

After patterning the photoresist layer 282, the mask layers 273, 272, 271 exposed by the photoresist layer 282 are partially removed and the fin structures 221 for the tap cells 220 are exposed. In some embodiments, the fin recess process is omitted. As shown in FIG. 10B, upper portions of the fin structures 221 are exposed. As shown in FIG. 10B, the mask layers 273, 272, 271 partially remain in the trench between the fin structures 221 and above the isolation region 210. Thus, the mask layers 273, 272, 271 form recess features 225. The recessed features 225 are disposed above the isolation region 210. As shown in FIG. 10B, a top surface 225t of the recess feature 225 is above the top surface 210t of the isolation region 210. A top surface 221t and sidewalls 221s of the fin structures 221 are exposed above the recessed features 225. The photoresist layer 282 is then removed for the epitaxial deposition.

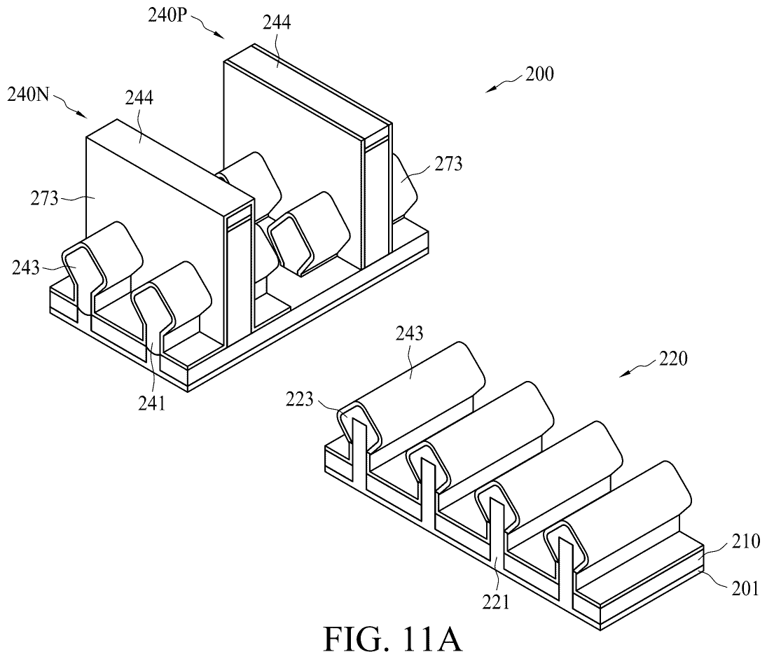

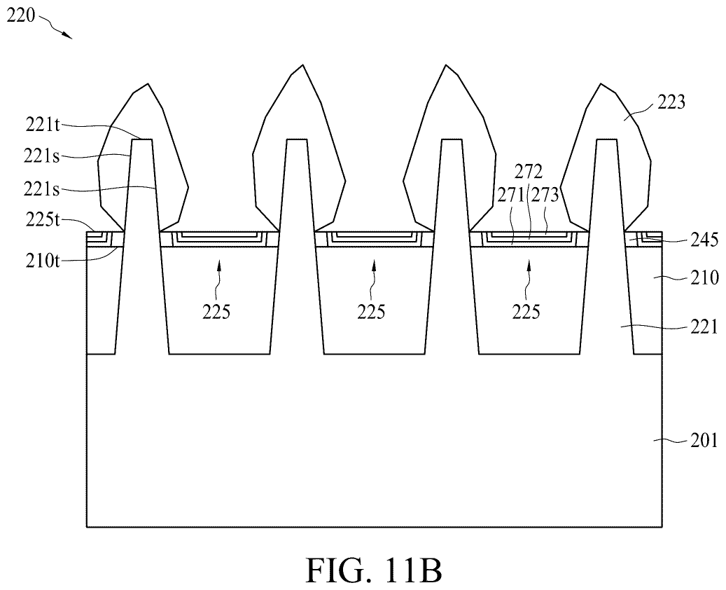

As shown in FIGS. 11A and 11B, the mask layer 273 covers the semiconductor materials of the source/drain regions 243 in the n-type device area and p-type device prevents further epitaxial growths on the source/drain regions 243. The epitaxial crown 223 for the tap cells 220 are grown from exposed semiconductor surfaces of the fin structures 221. In some embodiments, the epitaxial crowns 223 are grown from the top surface 221t and sidewalls 221s of the fin structures 221. The epitaxial crowns 223 are formed over the recess features 225. In some embodiments, the epitaxial crown 223 may be similar to source/drain regions of an NMOS transistor or a PMOS transistor.

In some embodiments, after forming the epitaxial crowns 223, the mask layer 273 may remain on the source/drain regions 243 for the p-type and n-type devices. The mask layer 272 may remain on the source/drain regions 243 for the n-type devices. In other words, the mask layers 272 and 273 cover the source/drain regions 243 of the n-type devices. The mask layer 273 covers the source/drain regions 243 for the p-type devices.

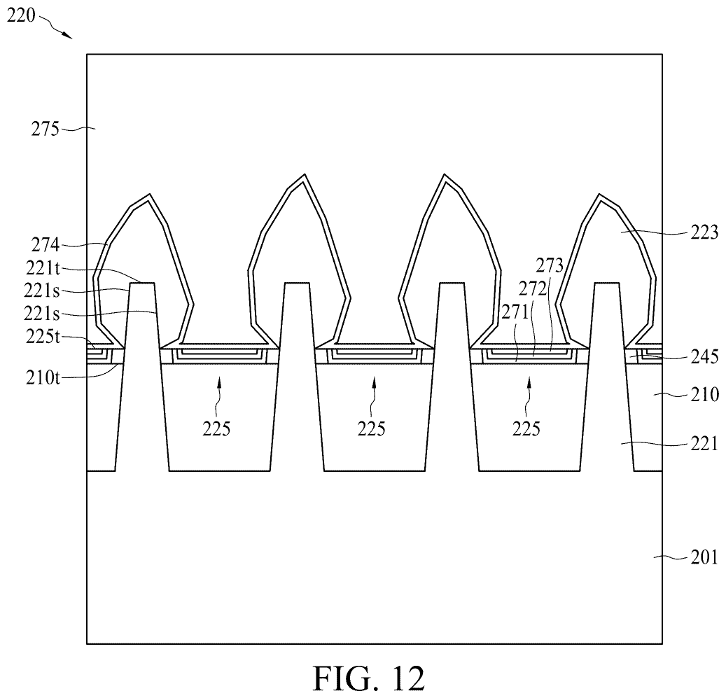

In FIG. 12, which is a cross sectional view of the tap cell 220, a contact etch stop layer (CESL) 274 is formed over the exposed surfaces. The CESL 274 is formed on the epitaxial source/drain regions 243, the epitaxial crowns 223, and the mask layer 273 or the recess features 225. In some embodiments, the CESL 274 has a thickness in a range between about 1 nm and about 15 nm. The CESL 274 may include Si₃N₄, SiON, SiCN or any other suitable material, and may be formed by CVD, PVD, or ALD.

An interlayer dielectric (ILD) layer 275 is the formed over the CESL 274. The materials for the ILD layer 275 include compounds comprising Si, O, C, and/or H, such as silicon oxide, SiCOH and SiOC. Organic materials, such as polymers, may be used for the ILD layer 275. After the ILD layer 275 is formed, a planarization operation, such as CMP, is performed to expose the sacrificial gate structure for a replacement process. The ILD layer 275 protects the epitaxial source/drain regions 243 and epitaxial crowns during the replacement gate process. During the replacement gate processes, the sacrificial gate dielectric layer and sacrificial gate electrode layer are removed to expose the fin structures 241. A gate dielectric layer in then over the fin structures 241 by CVD, ALD or any suitable method. The gate dielectric layer includes one or more layers of a dielectric material, such as silicon oxide, silicon nitride, or high-k dielectric material, other suitable dielectric material, and/or combinations thereof. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof. A gate electrode layer is formed on the gate dielectric layer. The gate electrode layer includes one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or combinations thereof.

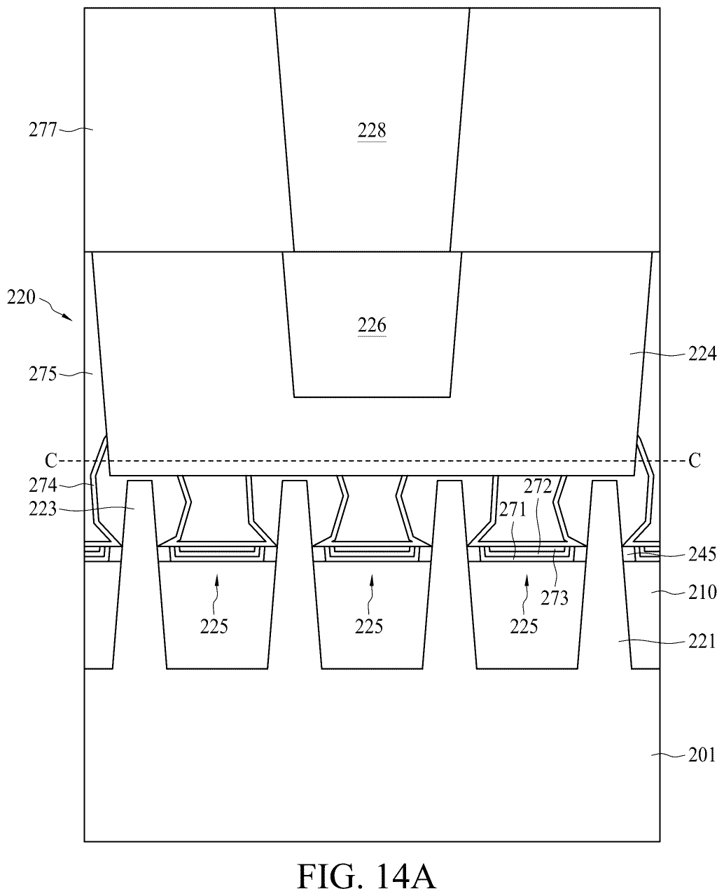

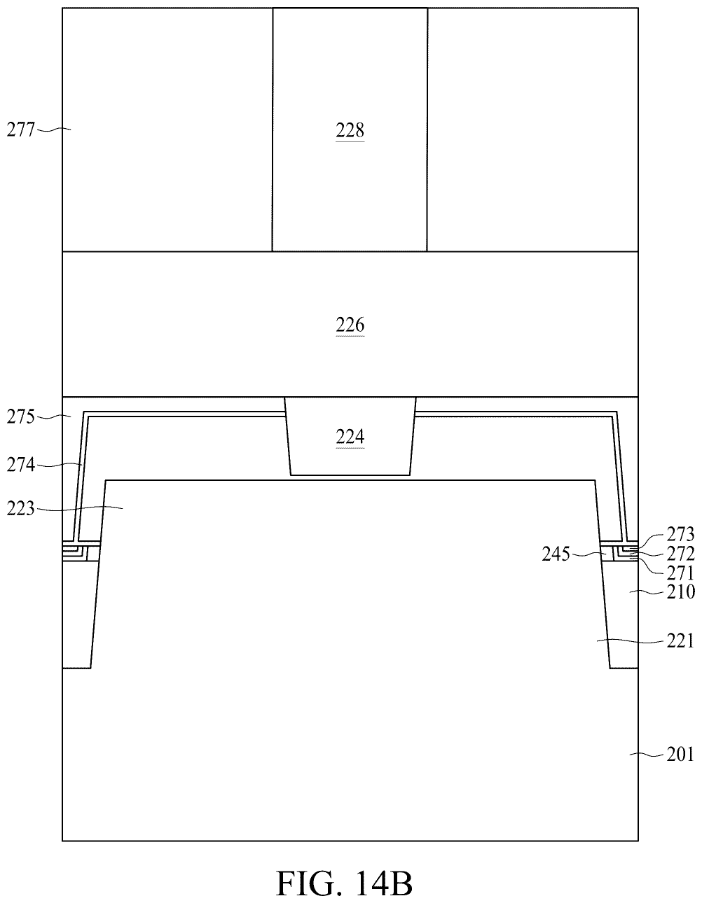

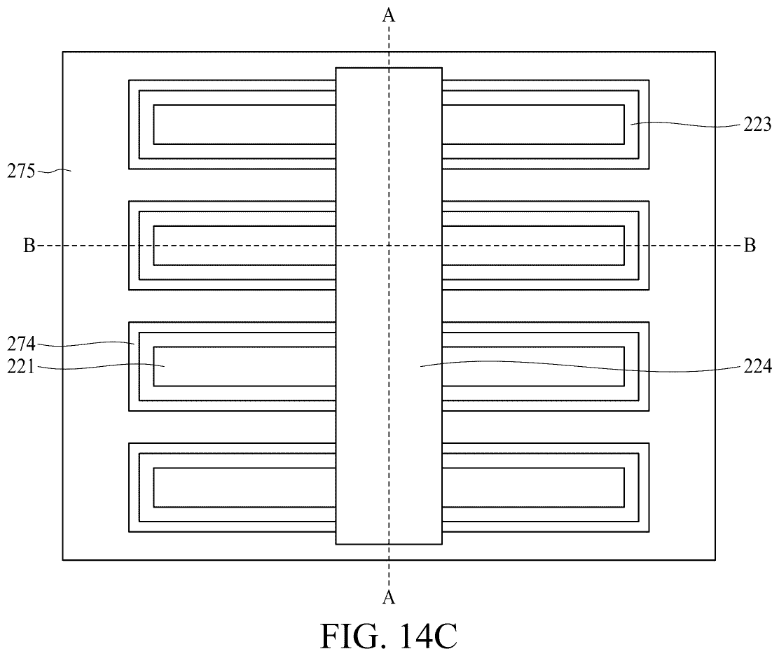

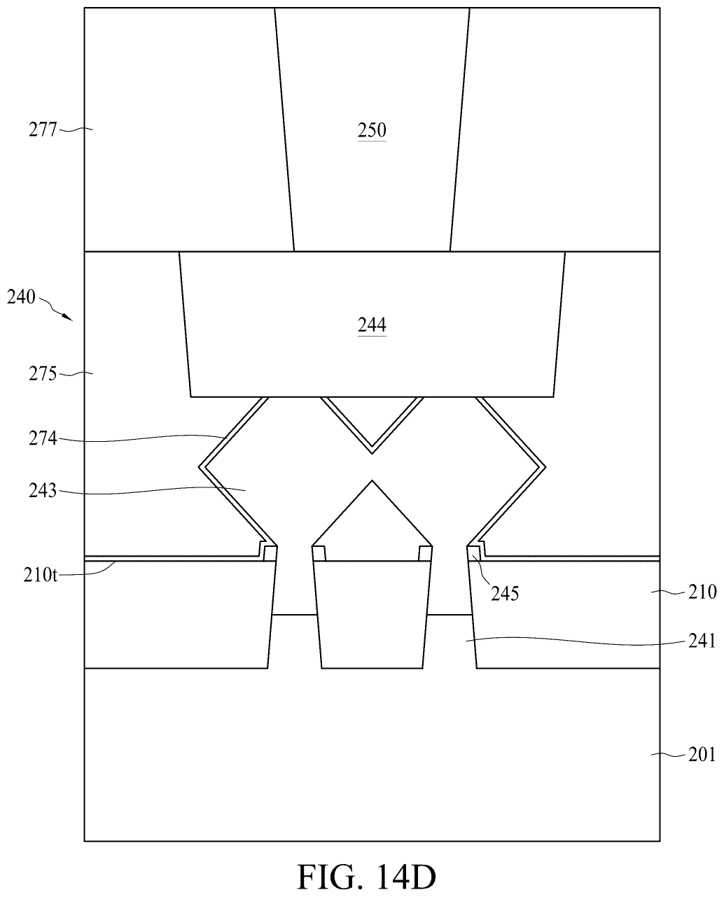

After the replacement gate process sequence, the contact features 224, 226 are formed in the ILD layer 275. A second dielectric layer 277 may be deposited over the ILD layer 275 and the conductive vias 228 may be formed in the dielectric layer 277, as shown in FIGS. 14A-14D. An interconnect structure, which includes multiple dielectric layers having metal lines and vias not shown formed therein, may be formed on the second ILD layer 277 and electrically connected to the transistors 240 and the tap cells 220. As shown in FIG. 14A, the epitaxial crowns 223 are disposed above the isolation region 210. The epitaxial source/drain regions 243, as shown in FIG. 14D, are partially disposed below the top surface of the isolation region 210. In some embodiments, the epitaxial crowns 223 may be disposed at a higher level along the z-direction than the source/drain regions 243.

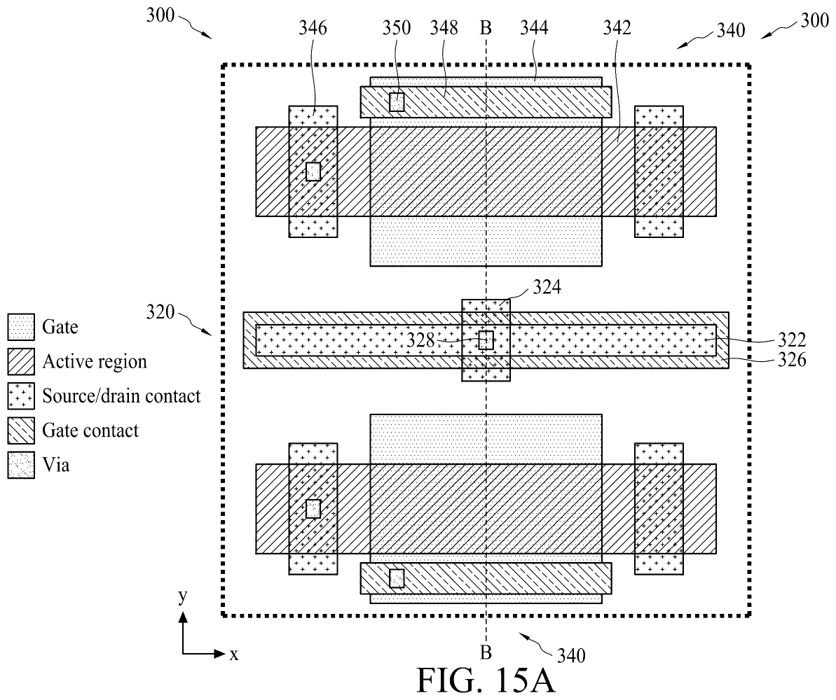

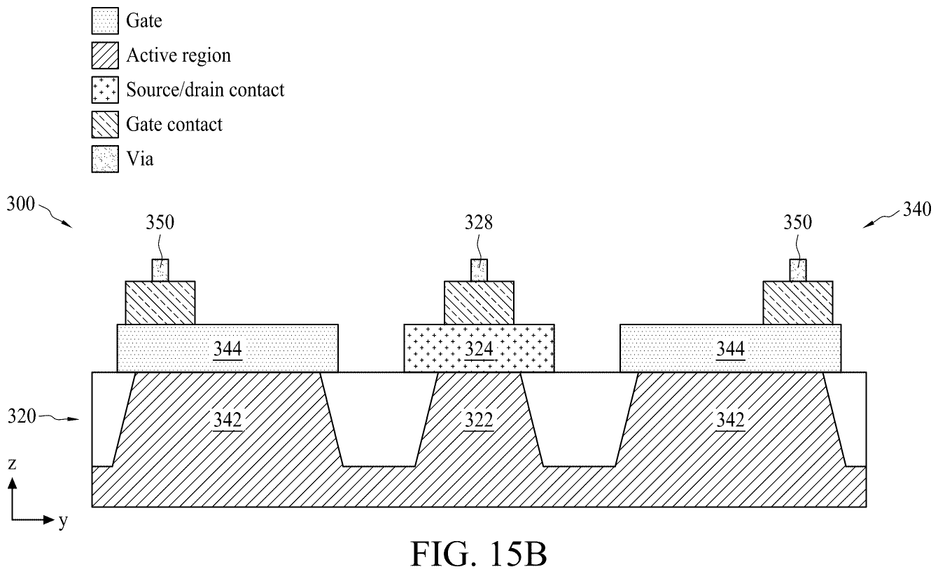

FIGS. 15A and 15B schematically illustrate a layout 300 according to embodiments of the present disclosure. The layout 300 is similar to the design layout 100 and circuit layout 200, except that the layout 300 includes planar devices. FIG. 15A is a diagram of an integrated circuit layout 300 including tap cells according to embodiments of the present disclosure. FIG. 15B is a cross sectional view of the integrated circuit layout 300 along B-B lines in FIG. 15A. The integrated circuit layout 300 may be a portion of an integrated circuit, such as an image signal processer. An image signal processer may include columns of ADC (analog digital converter), logic circuits, and DAC (digital analog converter). The layout 300 may include a tap cell 320 disposed between two transistors 340. The transistors 340 are planar devices. The transistors 340 may include active region 342 along the x-direction and gate structures 344 along the y-direction. Conductive features, such as source/drain contacts 346, gate contacts 348, and contact vias 350, formed over the active regions 342 and the gate structures 344.

In some embodiments, tap cells 320 between the transistors 340. In some embodiments, a single tap cell 320 is formed between the transistors 340. The tap cell 320 is configured to block noise between the transistors 240. The tap cell 320 may include a continuous conductive structure, which prevents electric signals from one side of the tap cell 320 across to the other side of the tap cell 320. In some embodiments, the tap cell 320 may include an active region 322 disposed along the x-direction. The active region 322 may extend substantially the entire length of the tap cell 320 along the x direction. Conductive features 324, 326, 328 are subsequently formed over the active region 322.

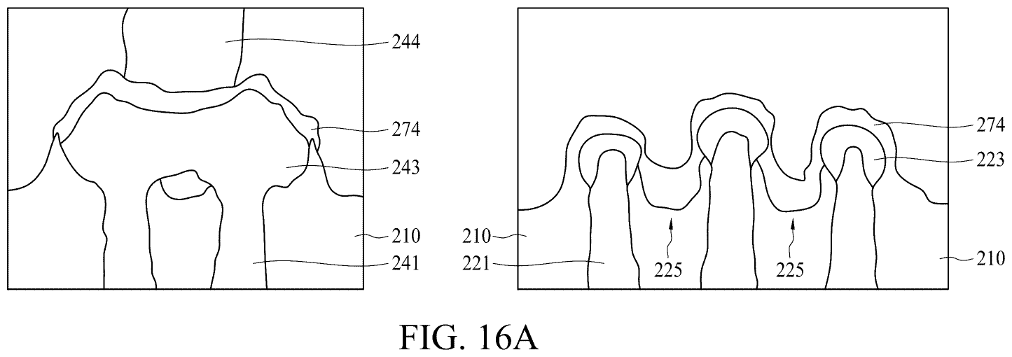

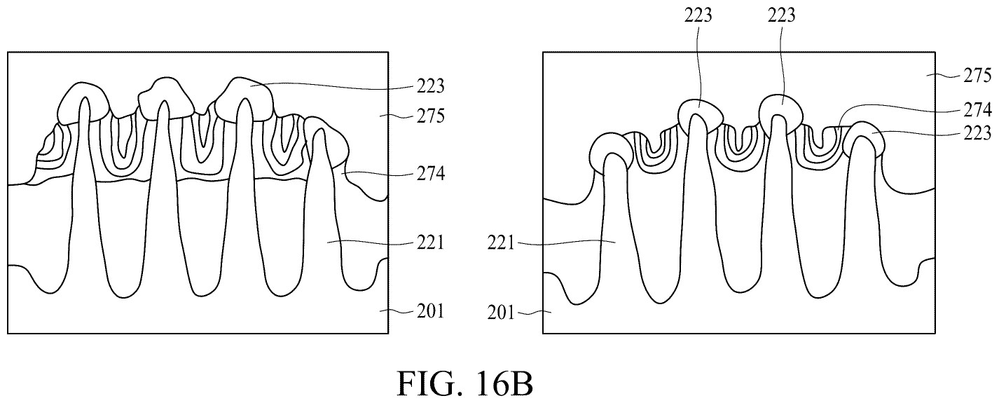

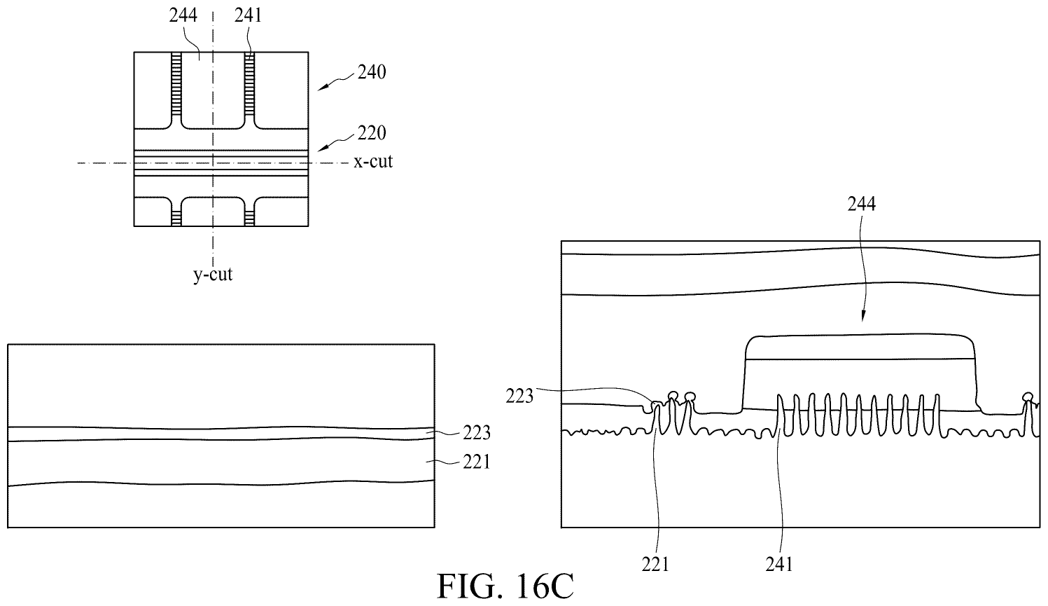

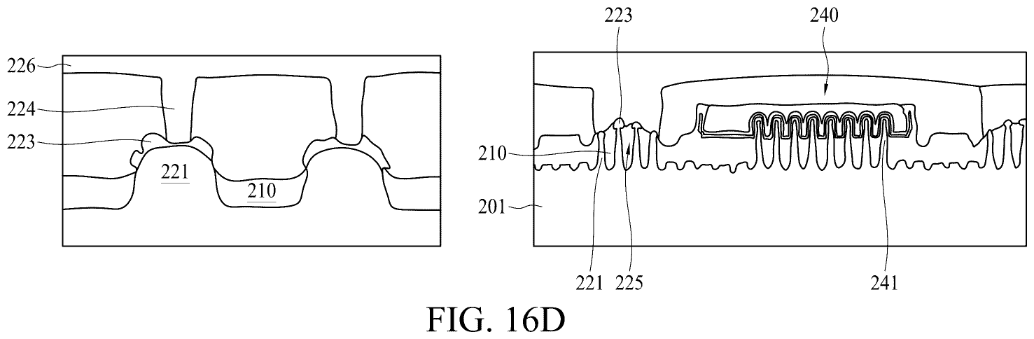

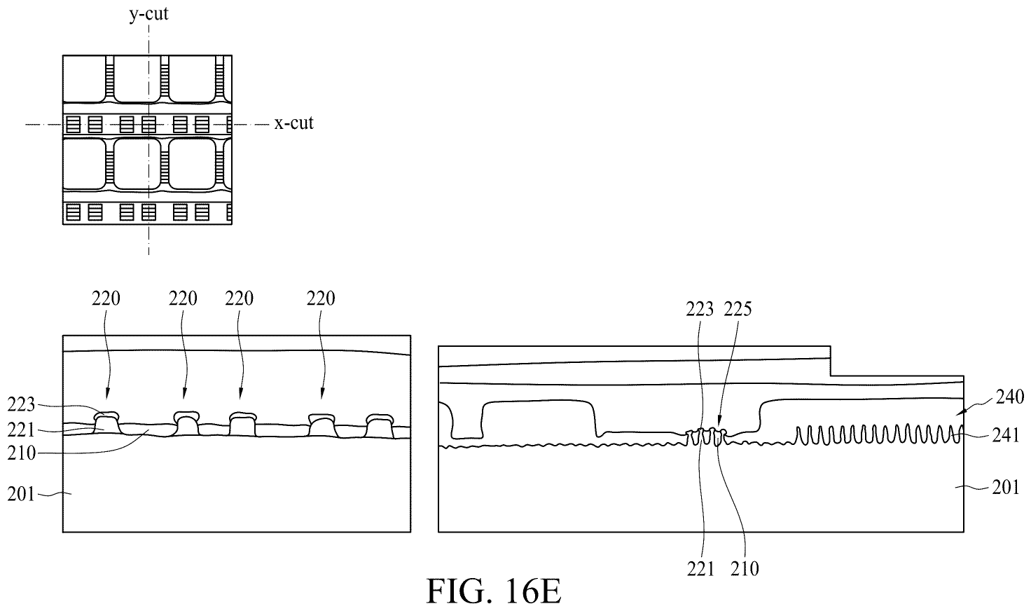

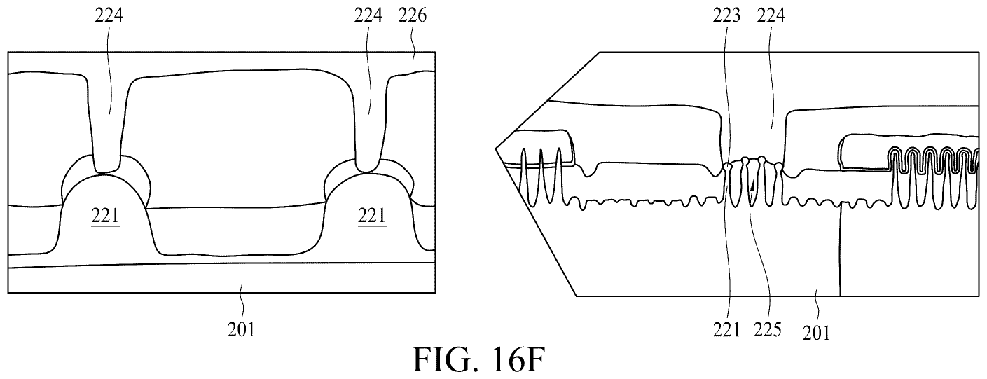

FIGS. 16A-16F schematically illustrate example tap cells according to embodiments of the present disclosure. In FIG. 16A, cross sectional views of a source/drain region of a n-type transistor and a tap cell with p-typed active region. As shown in FIG. 16A, the fin structure 241 for the n-type transistor has a larger pitch than the fin structures 221 of the tap cell. In FIG. 16B, cross sectional views of epitaxial crowns 223 formed from p-type epitaxial material and n-type epitaxial material. As shown in FIG. 16B, the n-type epitaxial crowns 223 have substantially triangular cross section while the p-type epitaxial crowns 223 has rounded cross sectional shape. Additionally, the epitaxial crowns 223 grown on outer fin structures 221 are lower than the epitaxial crowns 223 grown on center fin structure 221. In FIGS. 16C and 16D, cross sections of a tap cell with long active region are illustrated. In FIGS. 16E and 16F, cross sections of tap cells with short active regions are illustrated.

Various embodiments or examples described herein offer multiple advantages over the state-of-art technology. Embodiments of the present disclosure provide a tap cell without gate structures. By omitting gate structures, device density may be increased.

It will be understood that not all advantages have been necessarily discussed herein, no particular advantage is required for all embodiments or examples, and other embodiments or examples may offer different advantages.

Some embodiments of the present provide a tap cell, comprising: a first fin structure and a second fin structure formed on a substrate along a first direction; a first epitaxial crown disposed on the first fin structure; a second epitaxial crown disposed on the second fin structure; an isolation region disposed on the substrate and around lower portions of the first and second fin structures; a recess feature disposed on a top surface of the isolation region and between the first and second fin structures; and a contact etch stop layer disposed on the first and second epitaxial crowns and the recess feature, wherein the first and second epitaxial crowns are disposed above the recess feature.

Some embodiments provide an integrated circuit structure, comprising: a cell region disposed on a substrate, wherein the cell region comprises: a first transistor comprising first and second source/drain regions disposed along a first direction; and a gate structure disposed between the first and second source/drain regions, wherein the gate structure is along a second direction perpendicular to the first direction; and a tap region disposed on a boundary of the cell region on the substrate, wherein the tap region comprises: one or more tap cells disposed along the first direction, wherein the one or more tap cells are absent of gate structures.

Some embodiments of the present provide a method. The method comprising: forming two or more first fin structures in a cell region and two or more second fin structures in a tap region around the cell region on a substrate; forming an isolation region on the substrate around the first and second fin structures; depositing a gate dielectric layer and a gate electrode layer over the cell region and the tap region; removing the gate dielectric layer and the gate electrode layer from the tap region and forming a gate structure over the two or more first fin structures; depositing a first mask layer over the two or more first fin structures and two or more second fin structures; patterning the first mask layer to expose the two or more first fin structures; recess etching the two or more first fin structures to form source/drain recesses; forming source/drain regions in the source/drain recesses; depositing a second mask layer over the two or more second fin structures and the source/drain regions; patterning the second mask layer to expose the two or more second fin structures; removing the first and second mask layers to expose the two or more second fin structures; and forming epitaxial crowns on the two or more second fin structures.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A tap cell, comprising:
a first fin structure and a second fin structure formed on a substrate along a first direction;
a first epitaxial crown disposed on the first fin structure;
a second epitaxial crown disposed on the second fin structure;
an isolation region disposed on the substrate and around lower portions of the first and second fin structures;
a recess feature disposed on a top surface of the isolation region and between the first and second fin structures; and
a contact etch stop layer disposed on the first and second epitaxial crowns and the recess feature,
wherein the first and second epitaxial crowns are disposed above the recess feature.

2. The tap cell of claim 1, further comprising:
a first conductive feature in contact with the first and second epitaxial crowns, wherein the first conductive feature is disposed along a second direction perpendicular to the first direction.

3. The tap cell of claim 2, further comprising:
a second conductive feature in contact with the first conductive feature, wherein the second conductive feature extends along the first direction, the first and second fin structures have a first length along the first direction, the second conductive feature has a second length along the first direction, and the first length substantially equals to the second length.

4. The tap cell of claim 3, further comprising:
two or more first conductive features, wherein the two or more first conductive features are distributed along the first length of the first and second fin structures, and in contact with the second conductive feature.

5. The tap cell of claim 3, wherein the first and second fin structures comprise a doped semiconductor material, and the first and second fin structures, the first conductive feature, and the second conductive feature form a continuous conductive wall.

6. The tap cell of claim 2, wherein the first and second fin structures are continuous along the first length without encountering a gate structure.

7. The tap cell of claim 1, wherein the recess feature comprises:
a first mask layer in contact with the top surface of the isolation region; and
a second mask layer disposed over the first mask layer in contact with the contact etch stop layer.

8. The tap cell of claim 7, further comprising a third mask layer disposed between the first and second mask layers.

9. An integrated circuit structure, comprising:
a cell region disposed on a substrate, wherein the cell region comprises:
a first transistor comprising
first and second source/drain regions disposed along a first direction; and
a gate structure disposed between the first and second source/drain regions, wherein the gate structure is along a second direction perpendicular to the first direction; and
a tap region disposed on a boundary of the cell region on the substrate, wherein the tap region comprises:
one or more tap cells disposed along the first direction, wherein the one or more tap cells are absent of gate structures.

10. The integrated circuit structure of claim 9, wherein each of the one or more tap cells comprises:
two or more first fin structures disposed on the substrate along the first direction, wherein each of the two or more first fin structures comprises an epitaxial crown grown on the first fin structure;
a first conductive feature in contact with the epitaxial crowns of the two or more first fin structures; and
a second conductive feature in contact with the first conductive feature, wherein the second conductive feature extends along a length of the two or more first fin structures.

11. The integrated circuit structure of claim 10, wherein the tap region comprises a plurality of the tap cells disposed along the first direction, and a gap is formed between neighboring tap cells.

12. The integrated circuit structure of claim 11, wherein the gap is in arrange between about 2 nm and about 32 nm.

13. The integrated circuit structure of claim 10, wherein the cell region comprises one or more functional cells, and each of the one or more functional cells comprises:
two or more second fin structures disposed on the substrate along the first direction;
a gate structure disposed across the two or more second fin structures; and
source/drain regions disposed over the two or more second fin structures and on opposite sides of the gate structure, wherein the source/drain regions are at a vertical level lower than the epitaxial crowns of the one or more tap cells.

14. The integrated circuit structure of claim 10, wherein each of the one or more tap cells further comprises:
a recess feature disposed between the two or more first fin structures, wherein the epitaxial crowns are disposed above on a top surface recess features.

15. A method, comprising:
forming two or more first fin structures in a cell region and two or more second fin structures in a tap region around the cell region on a substrate;
forming an isolation region on the substrate around the first and second fin structures;
depositing a gate dielectric layer and a gate electrode layer over the cell region and the tap region;
removing the gate dielectric layer and the gate electrode layer from the tap region and forming a gate structure over the two or more first fin structures;
depositing a first mask layer over the two or more first fin structures and two or more second fin structures;
patterning the first mask layer to expose the two or more first fin structures;
recess etching the two or more first fin structures to form source/drain recesses;
forming source/drain regions in the source/drain recesses;
depositing a second mask layer over the two or more second fin structures and the source/drain regions;
patterning the second mask layer to expose the two or more second fin structures;
removing the first and second mask layers to expose the two or more second fin structures; and
forming epitaxial crowns on the two or more second fin structures.

16. The method of claim 15, wherein removing the first and second mask layers comprising:
exposing a top surface and sidewalls of the two or more second fin structures, wherein a recess feature comprising the first and second mask layers remain between the two or more second fin structures.

17. The method of claim 16, further comprising:
depositing a contact etch stop layer over the source/drain regions, the epitaxial crowns, and the recess feature.

18. The method of claim 17, further comprising:
depositing an interlayer dielectric layer over the contact etch stop layer; and
forming source/drain contact features and tap contact features in the interlayer dielectric layer.

19. The method of claim 18, further comprising:
forming a conductive line along the two or more second fin structures, wherein the conductive line is in contact with the tap contact feature.

20. The method of claim 19, further comprising: forming a plurality of second fin structures along the first direction, wherein a gap is formed between the two or more second fin structures.
